(19) United States
(12) Patent Application Publication
(10) Pub. No.: US 2017/0047708 A1
(43) Pub. Date: Feb. 16, 2017

(54) WAVEFUNCTION DECONFINEMENT ELECTRO-ABSORPTION MODULATOR

(71) Applicant: Finisar Corporation, Sunnyvale, CA (US)

(72) Inventor: Ralph H. Johnson, Murphy, TX (US)

(21) Appl. No.: 15/234,255

(22) Filed: Aug. 11, 2016

Related U.S. Application Data
(60) Provisional application No. 62/204,272, filed on Aug. 12, 2015.

(51) Int. Cl. H01S 5/06; H01S 5/024; H01S 5/34

(52) U.S. Cl. CPC H01S 5/06; H01S 5/34; H01S 5/0601; H01S 5/02453

(57) ABSTRACT

A method of modulating a laser device having an integrated modulator can include: emitting laser light from a primary laser cavity having quantum wells; passing the laser light through a modulator cavity having at least one modulator quantum well that is coupled with the primary laser cavity and integrated with the laser device; and biasing the modulator cavity so as to deconfine electron and/or hole wavefunctions in the at least one modulator quantum well of the modulator cavity such that the refractive index and absorption of the modulator cavity changes to modulate the laser light passing through the modulator. The method can include at least partially containing the deconfined electron and/or hole wavefunctions in a secondary modulator well region adjacent to a primary modulator well region, the primary modulator well region containing the at least one modulator quantum well.

### CROSS-REFERENCE

This patent application claims priority to U.S. Provisional Ser. No. 62/204,272 filed Aug. 12, 2015, which provisional is incorporated herein by specific reference in its entirety.

### BACKGROUND

Lasers are commonly used in many modern communication components for data transmission. One use that has become more common is the use of lasers in data networks. Lasers are used in many fiber optic communication systems to transmit digital data on a network. In one exemplary configuration, a laser may be modulated by digital data to produce an optical signal, including periods of light and dark output that represents a binary data stream. In actual practice, the lasers emit a high optical output representing binary highs and a lower power optical output representing binary lows. To obtain quick reaction time, the laser is constantly on, but varies from a high optical output to a lower optical output.

Optical networks have various advantages over other types of networks such as copper wire-based networks. For example, many existing copper wire networks operate at near maximum possible data transmission rates and at near maximum possible distances for copper wire technology. On the other hand, many existing optical networks exceed, both in data transmission rate and distance, the maximums that are possible for copper wire networks. That is, optical networks are able to reliably transmit data at higher rates over further distances than is possible with copper wire networks.

One type of laser that is used in optical data transmission is a Vertical Cavity Surface-Emitting Laser (VCSEL). As its name implies, a VCSEL has a laser cavity that is sandwiched between and defined by two mirror stacks. A VCSEL is typically constructed on a semiconductor wafer such as Gallium Arsenide (GaAs). The VCSEL includes a bottom mirror constructed on the semiconductor wafer. Typically, the bottom mirror includes a number of alternating high and low index of refraction layers. As light passes from a layer of one index of refraction to another, a portion of the light is reflected. By using a sufficient number of alternating layers, a high percentage of light can be reflected by the mirror.

An active region that includes a number of quantum wells is formed on the bottom mirror. The active region forms a PN junction sandwiched between the bottom mirror and a top mirror, which are of opposite conductivity type (e.g., a p-type mirror and an n-type mirror). Notably, the notion of top and bottom mirrors can be somewhat arbitrary. In some configurations, light could be extracted from the wafer side of the VCSEL, with the “top” mirror nearly totally reflective—and thus opaque. However, for purposes of this invention, the “top” mirror refers to the mirror from which light is to be extracted, regardless of how it is disposed in the physical structure. Carriers in the form of holes and electrons are injected into the quantum wells when the PN junction is forward biased by an electrical current. At a sufficiently high bias current the injected minority carriers form a population inversion in the quantum wells that produces optical gain. Optical gain occurs when photons in the active region stimulate electrons in the conduction band to recombine with holes in the valence band which produces additional photons. When the optical gain exceeds the total loss in the two mirrors, laser oscillation occurs.

The active region may also include an oxide aperture formed using one or more oxide layers formed in the top and/or bottom mirrors near the active region. The oxide aperture serves both to form an optical cavity and to direct the bias current through the central region of the cavity that is formed. Alternatively, other means, such as ion implantation, epitaxial regrowth after patterning, or other lithographic patterning may be used to perform these functions.

A top mirror is formed on the active region. The top mirror is similar to the bottom mirror in that it generally comprises a number of layers that alternate between a high index of refraction and a lower index of refraction. Generally, the top mirror has fewer mirror periods of alternating high index and low index of refraction layers, to enhance light emission from the top of the VCSEL.

Illustratively, the laser functions when a current is passed through the PN junction to inject carriers into the active region. Recombination of the injected carriers from the conduction band to the valence band in the quantum wells results in photons that begin to travel in the laser cavity defined by the mirrors. The mirrors reflect the photons back and forth. When the bias current is sufficient to produce a population inversion between the quantum well states at the wavelength supported by the cavity, optical gain is produced in the quantum wells. When the optical gain is equal to the cavity loss, laser oscillation occurs and the laser is said to be at threshold bias and the VCSEL begins to “lase” as the optically coherent photons are emitted from the top of the VCSEL.

The subject matter claimed herein is not limited to embodiments that solve any disadvantages or that operate only in environments such as those described above. Rather, this background is only provided to illustrate one example technology where some embodiments described herein may be practiced.

### SUMMARY

In one embodiment, a method of modulating a laser device having an integrated modulator can include: emitting laser light from a laser cavity having quantum wells; passing the laser light through a modulator cavity having at least one modulator quantum well that is coupled with the primary laser cavity and integrated with the laser device; and biasing the modulator cavity so as to deconfine electron and/or hole wavefunctions in the at least one modulator quantum well of the modulator cavity such that the refractive index and absorption of the modulator cavity changes to modulate the laser light passing through the modulator.

In one embodiment, a method of modulating a laser device having an integrated modulator can include: emitting laser light from a laser cavity having quantum wells;

passing the laser light through a modulator cavity having at least one modulator quantum well that is coupled with the primary laser cavity and integrated with the laser device; and applying bias to the modulator cavity so as to substantially increase the spatial volume occupied by the electron wavefunction and/or hole wavefunction from the at least one modulator quantum well of the modulator cavity such that the refractive index and absorption of the modulator cavity changes to modulate the laser light passing through the modulator.

In one embodiment, a method of modulating a laser device having a resonant integrated modulator can include: emitting laser light from a laser cavity having quantum wells; passing the laser light through a modulator cavity having at least one modulator quantum well that is coupled with the primary laser cavity and integrated with the laser device; and providing a defined electric field to the modulator cavity so that the index of refraction and absorption coefficient both decrease, then a nominal independent Fabry Perot resonance of the modulator cavity is longer wavelength than a Fabry Perot resonance of the laser cavity.

In one embodiment, the method of modulating a laser device having a resonant integrated modulator can include: emitting laser light from a laser cavity having quantum wells; passing the laser light through a modulator cavity having at least one modulator quantum well that is coupled with the primary laser cavity and integrated with the laser device; and providing a defined electric field to the modulator cavity so that one of the index of refraction or absorption coefficient increases and the other of the index of refraction or absorption coefficient decreases, then a nominal independent Fabry Perot resonance of the modulator cavity is shorter than a Fabry Perot resonance of the laser cavity.

### BRIEF DESCRIPTION OF THE FIGURES

The foregoing and following information as well as other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 includes an embodiment of an integrated modulator showing primary and secondary quantum wells.

FIG. 2 includes two periods of the integrated modulator of FIG. 1.

FIG. 3 includes an embodiment of an integrated modulator with a single primary well and secondary wells on either size at zero bias.

FIG. 4 includes an embodiment of an integrated modulator with a single primary well and secondary wells on either size at 0.2 volts reverse bias.

FIG. 5 includes an embodiment of an integrated modulator with a single primary well and secondary wells on either size at 0.33 volts reverse bias.

FIG. 6 includes a graph of the absorption data and refractive index data versus wavelength in relation to electric field bias in volts/micron for a series of 8 well pairs.

FIG. 7 shows an eight well simulation result for an unchirped structure with 8 primary wells and 8 secondary wells.

FIG. 8 is the first fit to measured extinction coefficient data on a non-optimized wavefunction deconfinement modulator active region.

FIG. 9 shows data of a contour plot of allowable ranges for a non-chirped structure between 70° C. to 90° C. for a transmission matrix simulation.

FIG. 10 shows data of a contour plot of allowable ranges for a non-chirped structure between 70° C. to 105° C. for a transmission matrix simulation.

FIG. 11 includes a schematic diagram of an embodiment of a VCSELs having the integrated modulator.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

Generally, the present technology relates to a modulator integrated in a VCSEL or edge emitting laser. The modulator offers primarily resistance/capacitance (RC) limited bandwidth, where RC can be very small depending on how small and highly doped the structures are. The laser having the integrated modulator can result in greater than 50 GHz bandwidth, and greater than 100 Gb/s may be achievable based on data.

The laser with integrated modulator can improve modulation of a semiconductor laser. Currently, direct modulation of semiconductor lasers is reaching limits in speed, but now the integrated modulator can provide increased speeds as described herein. Previously, some Stark shift modulators generally required the temperature being extremely well controlled in a narrow range, but now the integrated modulator of the present technology can operate in a broader range of temperatures with less precise control of the operational temperature range.

In one embodiment, the laser with the integrated modulator is operated so that the modulation effect is obtained from an effect that can be considered to be a parasitic effect on most Stark shift modulators. That is, the modulation effect used on the laser with integrated modulator as described herein has a parasitic effect on most Stark shift modulators. Most Stark shift modulators work by changing the band edge energy with an applied electric field. The Stark shift integrated modulator can be operated so that there is a change in the band edge energy from an applied electric field. At the same time the wavefunction overlap is decreased slightly causing a parasitic reduction in absorption in most Stark shift modulators.

Now, the decrease in wavefunction overlap can be used to reduce absorption in the integrated modulator. The absorption energy can also increase. By suitable design of the quantum well absorption region in the integrated modulator what was the parasitic reduction of absorption can be increased, and the Stark shift of the band edge can be decreased so that the parasitic reduction of absorption caused by decreased wavefunction overlap can be used as the primary modulation method of the lasers described herein. This is enhanced using a quantum well system where the electron wavefunction and hole wavefunction are confined in the same primary well at low applied electric fields, and at higher but easily achievable electric fields the electron and/or hole wavefunction resides mostly outside the primary well with a low overlap integral and in some designs can have a higher energy separation than at lower electric fields. As such, the integrated modulator can function with electron deconfinement modulation, or an electron and hole deconfinement modulation, or a hole deconfinement modulation.

In one aspect, when operating as an electron deconfinement modulator, the electron wavefunction can be deconfined from the primary well while the hole wavefunction still resides almost entirely in the primary well. This works because generally in direct gap material the density of states effective mass of holes is dramatically higher than that of electrons making them much easier to confine than electrons. The wavefunction overlap integral is thus decreased.

In one aspect, when operating as an electron and hole deconfinement modulator, both the electron wavefunction and hole wavefunction can be deconfined from the primary well. The electron and hole deconfinement modulator can be configured similarly with the electron deconfinement modulator embodiment; however, certain structural changes can optimize the structure for both electron and hole deconfinement. This embodiment operates as a wavefunction deconfinement modulator.

In one embodiment, with the enhancement of the sensitivity of the modulator device to an applied field, it is advantageous to use a secondary modulator quantum well that has a substantially wider gap quantum well with larger dimensions to provide a region for the wavefunction to reside under higher bias. The secondary modulator quantum well is designed so that absorption resulting from wavefunction overlap is substantially reduced and may be at a significantly shorter wavelength than the operating wavelength (e.g., laser light wavelength) of the laser device.

In one embodiment, the modulator quantum wells can be separated by barrier layers that have composition ramps. By ramping the barrier layer band offsets in the secondary well using compositional ramps, the classic band edge reduction of the Stark Shift is avoided.

In one embodiment, the primary modulator quantum well can include a cross-sectional profile (e.g., longitudinal cross-section cut in a longitudinal plane) that is substantially square, and the secondary modulator quantum well shape has monotonic compositional ramps on either side. In one embodiment, secondary modulator quantum wells are not square shaped (e.g., longitudinal cross-section). A shape for the secondary modulator well that has been shown to be useful is triangular instead of the classic square well. There are many arbitrary well shapes that will work, but generally they need to be shaped so that as the bands tilt the energy level does not decrease significantly. A nominally square well should be avoided as the secondary modulator well shape. Linear ramps, parabolic shapes and many others may be used.

In one embodiment, the primary modulator quantum well is substantially square, and the secondary modulator quantum wells are not square shaped. A shape for the secondary modulator well that has been shown to be useful is triangular instead of the classic square well. There are many arbitrary well shapes that will work, but generally they need to be shaped so that as the bands tilt the energy level does not decrease significantly. A nominally square well should be avoided as the secondary modulator well shape. Linear ramps, parabolic shapes and many others may be used.

Back reflection from the modulator into the primary VCSEL cavity (or other laser cavity, such as edge emitter) can cause modulation of the primary laser making the device less useful due to pattern dependent eye closure, but now the integrated modulator can operate with nominally constant back reflection operation to avoid the pattern dependent eye closure.

In one aspect, the laser uses an electric field across the integrated modulator quantum wells nominally inside a PIN junction to cause the charge carrier states to deconfine (e.g., electron deconfinement or electron and hole deconfinement). As such, the modulator is a wavefunction deconfinement modulator.

The wavefunction deconfinement modulator can cause a rapid change in absorption in an optically-active region and a change in the index of refraction of the optically-active region which is useful in an electro-optic/electro-absorption, EO/EA, modulator. The modulator, including the optically active region, can be integrated in the structure with the lasing active region, which can be by monolithic integration, epitaxial integration, or other integration of semiconductor regions. The modulator can be integrated in the semiconductor structure in a section which is resonant. By tuning the resonance of the modulator section about the lasing wavelength using the change in refractive index combined with the change in absorption, the back reflection change with modulation into the laser can be kept relatively small while synergistically these two effects (e.g., change in absorption and change in refractive index) can be used together to enhance modulation. This is done by increasing back reflection caused by a refractive index shift and at the same time decreasing back reflection caused by increased absorption for the low light output state and vice versa for the high output state. That is, for the state when the laser combined with the modulator has a low slope efficiency the resonant modulator (e.g., electro-optical and electro-absorption, EO/EA) is highly absorbing, and the Fabry-Perot (e.g., FP) resonance is detuned from the lasing wavelength significantly to enhance back reflection making up for the loss of back reflection due to absorption. For the light transmitted, the effects combine synergistically to enhance modulation. That is, the two states are high absorption and high reflection, and low absorption and low reflection with no net change in back reflection into the laser, but a large change in the transmitted light. As such, modulation can be performed by the integrated modulator. In one aspect, back reflection is taken care of by design or dual modulation (see U.S. Ser. No. 14/698,180, incorporated herein by specific reference) or both. A large enough temperature range is achieved with wavefunction deconfinement modulation instead of the Stark shift.

In one embodiment, the modulator cavity can include primary quantum wells and secondary quantum wells. A secondary quantum well may be provided so that the lower energy electron wavefunctions partially or substantially resides in it with high applied electric fields, while the lower energy hole wavefunctions remain trapped in the primary quantum well or the hole wavefunction may also transfer to the larger energy secondary well. In the case of both carrier wavefunctions transferring to the secondary well, the wavefunction overlap integral is still reduced due to the mismatch of the shapes and positioning.

In one aspect, a secondary quantum well provides the wavefunctions with a larger energy separation than the primary well. The larger energy separation can be obtained so that wavefunction overlap (wavefunction overlap integral) is at higher energy separation than the operating photon energy of the laser. In one aspect, a secondary quantum well profile is designed with band offset ramps instead of a square profile so that the absorption edge is not reduced with higher applied fields. In one aspect, a secondary quantum well is designed using any shape to minimize the reduction of the energy level with increased electric field.

In one aspect, the laser with the integrated modulator can operate under increased temperature ranges, where the temperature ranges can be at a usable temperature value. The laser is configured to modulate the overlap of the electron and hole wavefunctions in the primary well instead of the band edge shift by using the electric field to deconfine the electron wavefunction, hole wavefunctions, or both electron and hole wavefunctions thereby enhancing the temperature range. This is enhanced further by chirping the quantum wells, so that different quantum wells are more optically useful at different wavelengths. While this decreases the peak effect and thus the peak extinction ratio, it enhances the allowable temperature range. Chirping the wells means varying the well thickness through the structure so the modulator is useful over a broader range of wavelengths and thus a broader range of temperatures. The quantum well thickness variation is found to be most optimal when there are more of the shorter wavelength absorbing quantum wells than long wavelength absorbing quantum wells. In one aspect, the number of shorter wavelength absorbing quantum wells is three times the number of long wavelength absorbing quantum wells.

In one embodiment, the laser with the integrated modulator can operate with electron deconfinement and/or hole deconfinement. In one aspect, the operational method can use hole deconfinement.

In another aspect, the electron deconfinement can be favored in some instances because the electron wavefunction can almost completely be removed from the quantum well and the hole wavefunction is retained in the quantum well for some structures with higher valence band offsets. The valence band offset for some materials when combined with the high effective mass can result in significant confinement in the valence band, and thereby making it difficult to deconfine the hole wavefunctions, and making it relatively easier to deconfine low effective mass electron wavefunctions. Accordingly, wavefunction deconfinement can be used in edge emitters also. Back reflection variations can be reduced by using a one pass non-resonant modulator section, preferably with an AR output coupler on the modulator. Back reflection variation effects can be reduced using a long photon lifetime low ROF primary laser, where such a laser can help increase reliability using lower current densities, or material choices which are slow, but reliable.

In one aspect, the laser with the integrated resonant modulator is configured so that the modulator resonance does not overlap the lasing wavelength, but has some separation. It is this nonalignment which causes the shift in refractive index, which mathematically results from Kramers Kronig relations and is related to the change in absorption, to be a useful aspect of modulating the device. There are various ways to set the modulator resonance to be separate from the lasing wavelength. In one aspect, the band edge Stark shift is employed. In one aspect, fully optimizing for electron deconfinement is not employed in instances the band edge Stark shift is employed. In one aspect, it can be beneficial to use a distributed feedback (DFB) laser to set the wavelength, and adjust the temperature as required for the modulator to perform. In one aspect, use of band filling to adjust wavelength in the primary laser can be beneficial. In one aspect, a heater can be included on the integrated modulator. Thus, any one or more of these configurations can be employed to set the modulator band to not overlap the lasing wavelength by an amount useful to achieve modulation and avoid back reflection variation by using synergistically the absorption change and index change to modulate the transmitted light, but at the same time using their dissimilar effects on the back reflection to minimize change in back reflection.

In one embodiment, utilizing laser configurations that provide wavefunction deconfinement can be suitable for edge emitters with DFBs. In part, this is because the added wavelength range of the modulator can translate into added temperature range versus a band edge Stark shift modulator.

In one embodiment, the low carrier confinement that is obtainable for operation of the integrated modulator can result in shorter transit times. These shorter transit times can be obtained in any of the embodiments of integrated modulator as described herein.

In one embodiment, the deconfinement modulator is not integrated with the laser but is a separate component which can modulate reflection or transmission, or both. The modulation effect can be enhanced by placing the modulating section inside a resonant cavity.

In one embodiment the deconfinement modulator is not integrated with the laser but is a separate component tilted with respect to the incident laser light to provide a useful path for the reflected light. The modulation effect can be enhanced by placing the modulating section inside a resonant cavity.

In one embodiment the deconfinement modulator is not integrated with the laser, but is a separate component which is tilted with respect to the laser light. By being tilted, the transition strength varies with angle and polarization so that polarization components can be modulated with reflection or transmission. The modulation effect can be enhanced by placing the modulating section inside a resonant cavity.

In one aspect, the integrated wavefunction deconfinement modulator can be configured for the top of a VCSEL. This can include the VCSEL including the integrated modulator in a resonant coupled cavity of the laser. In other technologies, the band edge shift using the quantum confined Stark shift may be difficult to use because the temperature control must be very precise. Now however, it has been determined that it is possible that there is a parasitic effect on the band edge Stark shift, and as a result the wavefunctions lose overlap. By optimizing for this parasitic effect on the band edge Stark shift instead of maximizing the band edge reduction of the normal Stark shift the temperature range can be expanded significantly. This protocol can be summarized as wavefunction deconfinement modulation. Such wavefunction deconfinement modulation can be implemented by a structure in which an applied bias causes quantum wells in the integrated modulator to switch to a condition without a confined state (e.g., electron deconfinement or electron and hole deconfinement). The effect can result in a broad wavelength band because the laser can have the wavelength range between the original quantum well absorption and the continuum absorption. As a result, this allows a much broader temperature range.

In one embodiment, the integrated modulator is an electro-absorption modulator. The electro-absorption modulator is configured so that a possibly formerly parasitic effect is utilized for enhancing laser modulation. The electro-absorption modulator can operate by applying increasing reverse bias to it so that the absorption decreases, which go downward with the bias. The increase in the absorption edge in the region marked with the arrow shows the standard band edge Stark effect with the limited useful wavelength range of ˜3 nm which translates to ˜11 C useable temperature range, which is not adequate. The incorporated provisional application shows data for a quantum well coupled pair with Stark shift band edge modulation. This absorption reduction can be considered to be a parasitic effect in this case. The present configuration using the absorption reduction can be used as opposed to a normal Stark shift band edge shift used in Stark shift modulators that require precise temperature control. Thus, the embodiments of the laser with the deconfinement modulator can advantageously be used in environments without temperature control (or little temperature control). The laser with the integrated deconfinement modulator can operate over a substantial wavelength range, greater than the 3 nanometers shown here for the band edge effect.

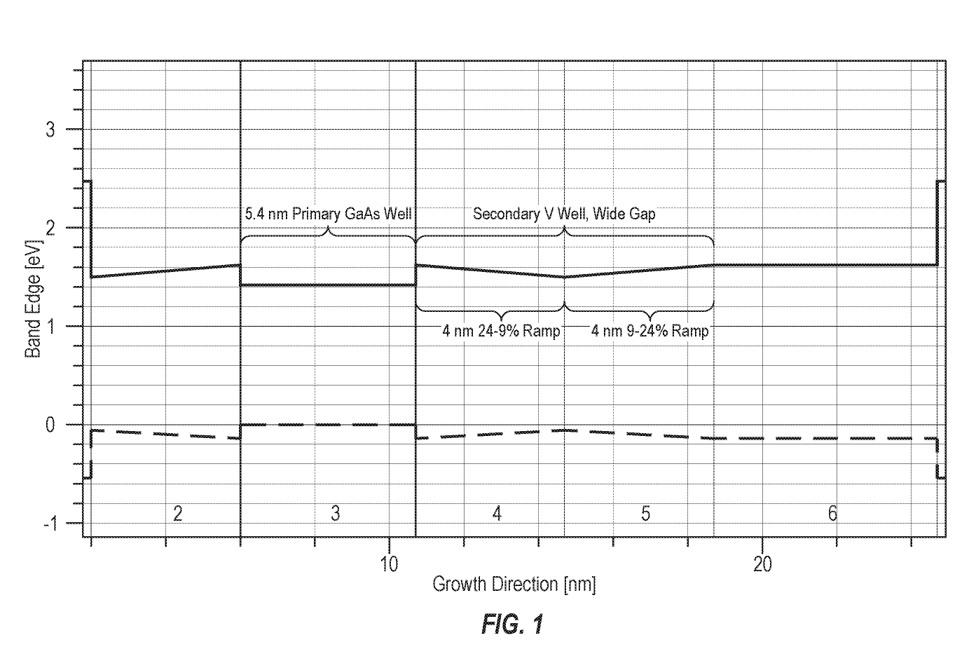

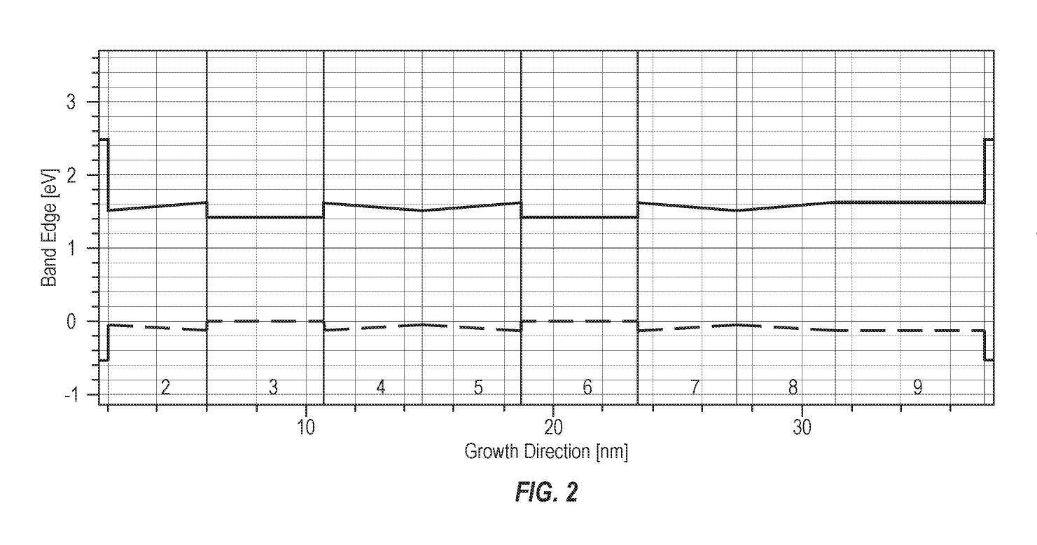

Turning to FIGS. 1 and 2, an embodiment of an integrated modulator is illustrated, where FIG. 2 illustrates two periods of the primary-secondary quantum well pairs. FIG. 1 shows a structure with one period of a wavefunction deconfinement electro-absorption modulator quantum well absorber. However, it should be recognized that any suitable number of periods can be used, but there are only two periods illustrated so that configuration can be analyzed. The configuration shows two tapered shaped quantum wells and a secondary quantum well in between the tapered shaped quantum wells. As shown, there is a slight depression for the secondary quantum well. For an integrated resonant modulator on top of a VCSEL there may be on the order of 30 pairs of these wells.

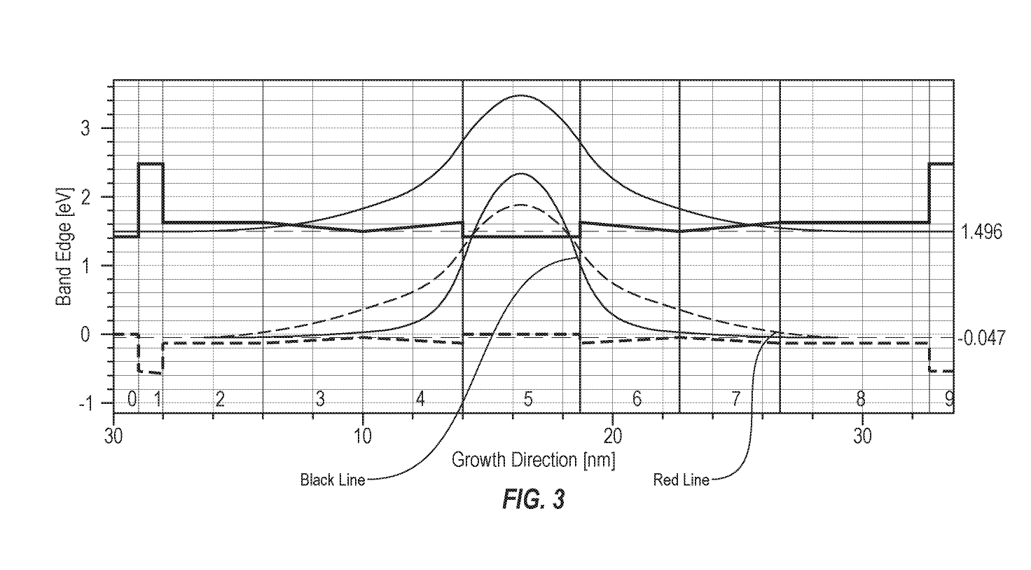

For purposes of illustration, but not meant to be an accurate calculation FIG. 3 shows a single primary well and a secondary well on either side at zero bias. For example, in FIGS. 3-5 bias means the applied voltage across the simulated region. No built in voltage or doping is used for these particular simulations. The wavefunctions are substantially confined into the primary well. That is, at zero bias, the lowest states can be confined. The absorption is maximized when the matrix element integral is maximized, which is when wavefunctions overlap with similar shapes as is shown in FIG. 3. The valence band black curve is the heavy hole band and the red curve is the light hole band wavefunctions. This shows the lowest electron wavefunction and the heavy hole and light hole band at zero bias, Note the high overlap and similarity of shape of the wavefunctions giving a high matrix element and resulting in a high absorption.

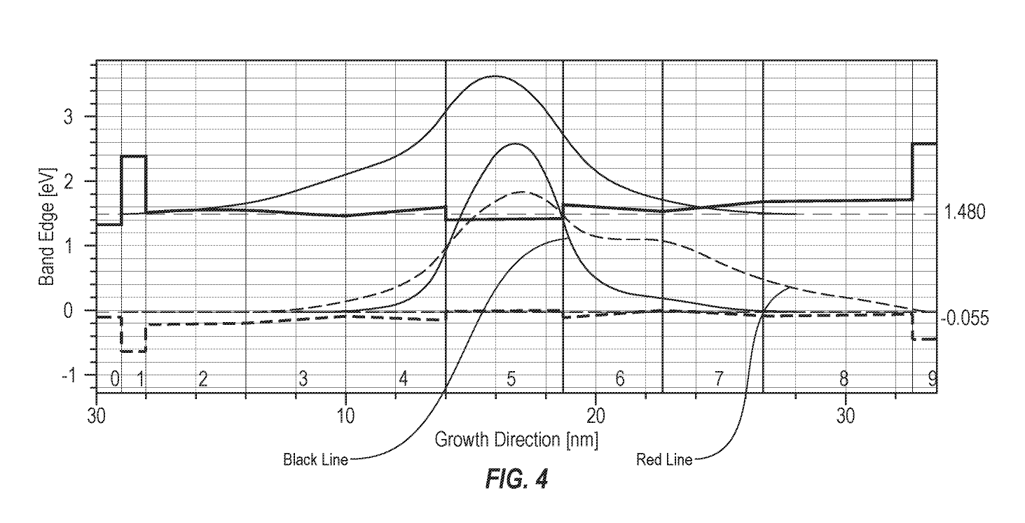

Turning to FIG. 4, at 0.2 volt (reverse 0.2) bias, the lowest conduction band state and lowest separation (e.g., highest) hole state, the heavy hole state, are still confined while the light hole wavefunction is losing confinement. The heavy hole band is much more important for absorption because of the much higher density of states than the light hole band. At 0.2 volts the light hole band is losing confinement, but the heavy hole band and electron band remain confined.

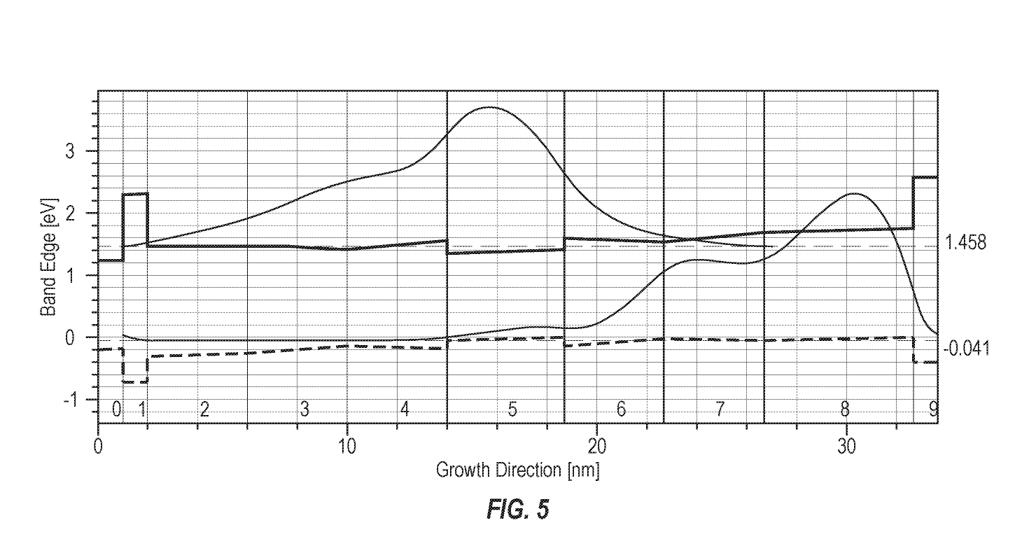

Turning to FIG. 5, at 0.33 volts (reverse 0.33 volt) bias, the heavy hole and electron wavefunctions are no longer confined to the primary well but spread into the secondary well. In a real device the artificial barriers at the ends do not exist and the wavefunctions can spread further. In a real device there is still overlap of the wavefunctions because the periodic nature makes the two secondary wells equivalent, but the wavefunctions are spread out and not similarly shaped or positioned thereby reducing the matrix element substantially. Heavy hole and electron wavefunctions strongly deconfined with more field (0.33 volts)

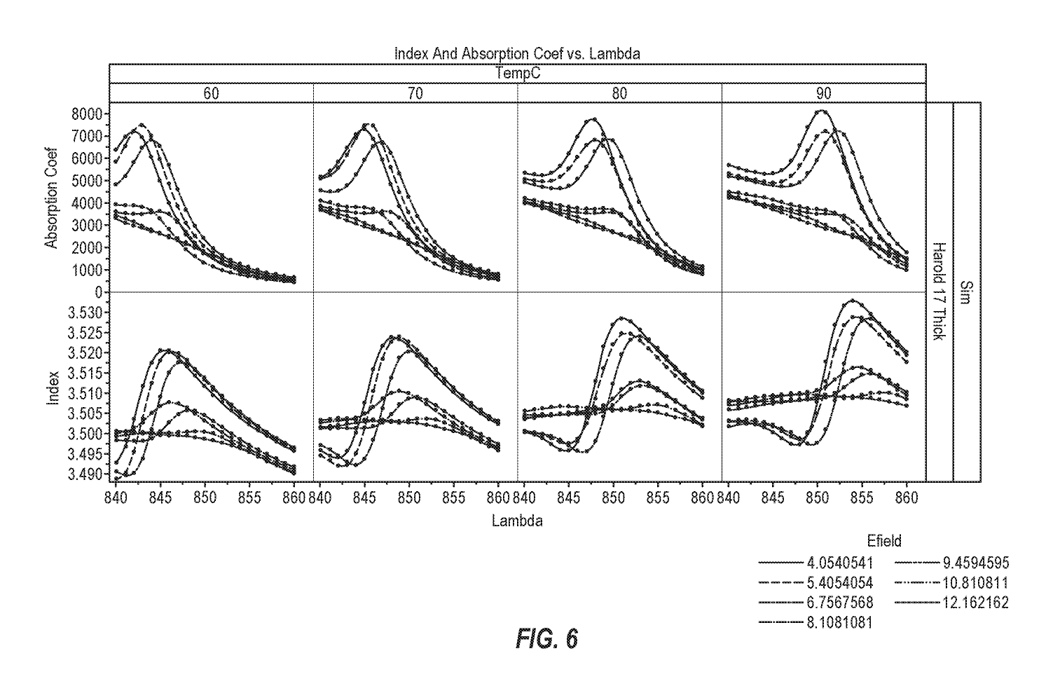

FIG. 6 shows a graph of the absorption data in relation to electric field bias in volts/micron for a series of 8 well pairs, which indicates that part of the large reduction in the absorption with the change in bias can be over a substantial wavelength range. The data shows the absorption coefficient and index of refraction vs wavelength at various applied fields and temperatures. It was found that 8 well pairs is an accurate approximation for a large number of well pairs, such as for example 28 well pairs. This shows wavefunction deconfinement modulation by changing the absorption in the modulator to modulate the laser. Thus, using wavefunction deconfinement to change absorption can perform laser modulation. Since the laser with the integrated modulator is configured to deconfine the wave functions with bias and it can modulate the absorption with a high change in absorption, the integrated modulator is useful over a wider wavelength range. For example, the wavelength range can be about 850 nm to 860 nm or 840 nm to 850 nm, or 842 nm to 848 nm for a particular design. This is useful to both expand the temperature range, and allow for multimode devices.

FIG. 6 shows also how the index of refraction changes with applied bias. This shows the benefit of using both the change in absorption and index of refraction synergistically to enhance modulation as well as reduce back reflection variation.

Data in the incorporated provisional shows optimization for the Stark shift, which indicates the band edge shifting with bias. The data shows the band edge shifting; however, the absorption goes up and down more significantly and has less band edge shift. This data shows the difference between the way two structures work (e.g., Stark shift versus wavefunction deconfinement), where the configuration for wavefunction deconfinement indicates a significantly large wavelength range for operation and modulation of the laser, which translates into a wider operating temperature range with wavefunction deconfinement.

The equation for the transition matrix element connecting the wavefunctions for the two states (e.g., wavefunction for initial state and wavefunction for final sate) is as follows:

M_{if}=∫Ψ_{f}VΨᵢdv

The matrix element M_{if} is related to the absorption coefficient and emission. In the case of the laser with the integrated modulator, absorption is determined. Absorption and laser emission can be thought of similarly, except for statistics. In the equation Ψ_{f} is the final state wavefunction and the Ψᵢ is the initial state wavefunction. Usually the V (e.g., operator for the physical interaction which couples the initial and final states of the system) can be pulled outside of the integral as an approximation because it is often about constant over the spatial extent of the wavefunction. Generally, if there is a higher overlap integral between the two wavefunctions, the result is a bigger matrix element, and the matrix element can determine the absorption coefficient. Accordingly, when having a hole state, such as when the hole states are confined to the well and the electron states are spread out, then there is not going to be much absorption. On the other hand, if the hole wavefunctions are spread out, but the hole states are at an energy so that the light cannot be absorbed because the states are too far apart energetically, then the modulator does not have significant absorption. The integrated modulator can operate by decreasing the overlap of the wavefunctions at lower energy splitting by applying bias, and where the remaining states have energy splitting between the electron states and hole states that is too large for them to affect the absorption at the operating wavelength. At the desired wavelength, the deconfining of the wavefunctions spreads the wavefunctions out so the overlap integral between the electron and hole wavefunction is reduced, and that causes a reduction in absorption. As such, modulating the states can turn the absorption on and off rapidly. In one example, as the device applies more reverse bias to the integrated modulator, the wavefunctions spread out and the overlap integral of the hole wavefunction and the electron wavefunction for the energy/wavelengths decreases, which results in the absorption coefficient of the integrated modulator decreasing. On the other hand, at higher energy this operational paradigm may not be beneficial; however, in a significant range of wavelengths the operational paradigm works and allows for emitting a modulated laser beam from the laser with the integrated modulator over a significant range of wavelengths.

When the device applies more reverse bias to the deconfinement modulator, the absorption coefficient decreases, which results in more bias letting more laser light be emitted from the laser. Then, the device can reduce the reverse bias in order to increase the absorption coefficient, and the increased absorption coefficient causes the integrated modulator to absorb more laser light that effectively blocks light emission from the laser. This allows modulating the bias to the integrated modulator in order to modulate data onto the laser light.

In one embodiment, the laser with the integrated modulator can be operated to utilize the change in index of refraction which occurs with the change in the absorption. This can be calculated using the Kramers Kronig relations. The operation can utilize misalignment of the Fabry Perot (FP) resonance (or dip) of the modulator cavity vs the FP resonance of the laser cavity. The FP dips are reductions or troughs in reflectance of a FP resonator, where the integrated modulator cavity and primary laser cavity can have properties of a FP resonator, where the reflectance dips can be more closely aligned or more unaligned. Accordingly, the alignment of the Fabry Perot dips in the integrated modulator cavity compared to the Fabry Perot dips in the primary laser cavity can be misaligned by an amount controlled by the applied bias to alter reflection and transmission, and thereby contribute along with the absorption change synergistically to modulation. By using the shift in refractive index and unaligned Fabry Perot dips of the modulator versus the primary laser cavity, the device can have large modulation with the synergistically used changes in absorption and index of refraction. This can also allow for keeping the back reflection to the primary laser cavity constant. To accomplish this when there is no shift in refractive index, the Fabry Perot dips are misaligned causing higher reflection back towards the laser with the resulting lowered transmission, simultaneously there is also high absorption for less emitted laser light. At this same condition due to the high absorption there is also low reflected light compensating for the high reflected light caused by the misalignment of the FP dips causing the reflected light to remain constant. A change in bias can be used to change the index of refraction which reduces the unalignment (e.g., offset) of the Fabry Perot dips and reduces the absorption both of which enhance transmission to effect modulation and comprises the high transmission state.

For example, when having two mirrors that are not perfect reflectors, and they are close to each other, the reflectance of light can be high, but when there is a particular wavelength of light, it builds up a resonance inside the cavity, and the reflectance back up toward the top of the cavity device can go all the way to zero depending on the reflectance of the two mirrors, which can give about 100% reflectance transformed to zero reflectance at the resonance of that cavity. Now, by combining two FP resonators, one being the primary laser cavity and the other being the modulator cavity, the relation of the FP resonance dips between the two different cavities can be shifted in relation to each other with bias. This allows for changing the reflection and transmission of the laser light.

At the least reverse bias to be used the lowest index wavefunctions must have a high overlap integral and thus a high transition matrix element. This maximizes the initial absorption. As the reverse bias is increased, the wavefunctions can lose confinement in the quantum well moving primarily outside the quantum well to optionally a secondary higher energy quantum well. The higher energy conduction band wavefunctions may not couple well to the fundamental hole wavefunctions. The higher transition energy hole states (lower energy) can be at a low enough energy that the transition energy is out of the region of interest. The change in reflectance due to refractive index change can work synergistically with the change in absorption to modulate the transmission, and thus the slope efficiency. The change in reflectance back to the laser can be configured to remain approximately constant by balancing the reflective and absorptive changes in the modulator.

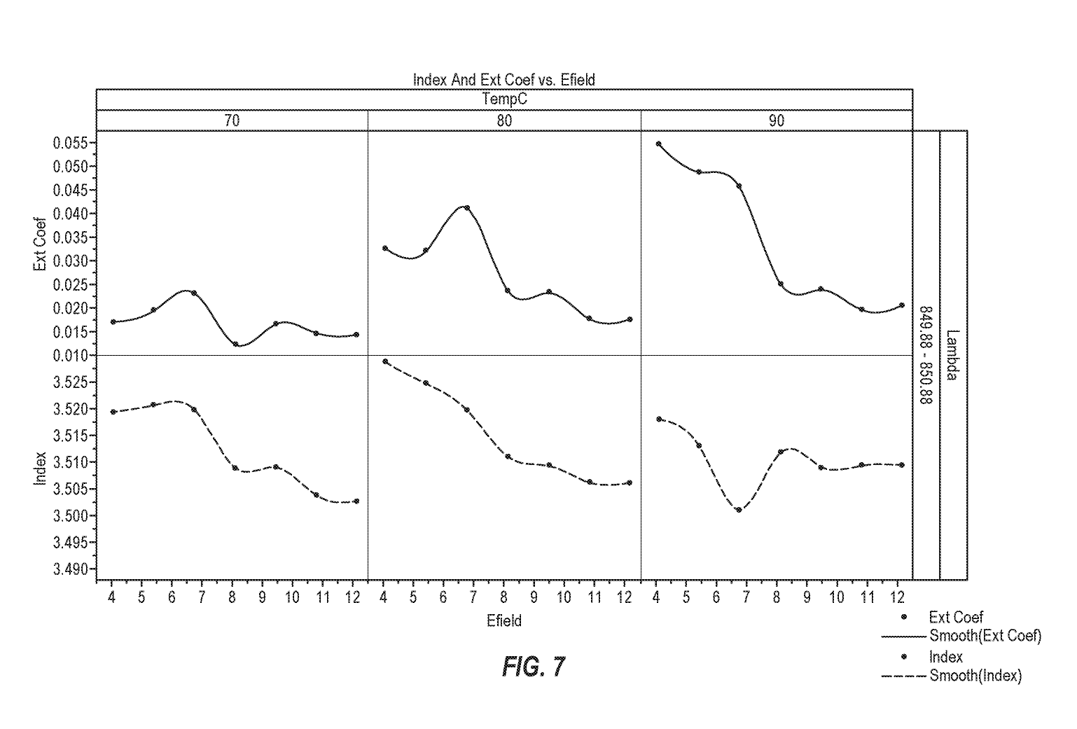

FIG. 7 shows an eight well simulation result for an unchirped structure as in FIG. 2, except it has 8 primary wells and 8 secondary wells. The data shows the extinction coefficient (lambda/4PI*absorption coefficient) decreases with increasing reverse bias, shown here as an increasing electric field. At the same time the index is generally decreasing. With both of these decreasing with more applied electric field the FP dip of the modulator must be longer than the lasing wavelength to achieve the synergistic modulation of the output and keep the back reflection relatively constant. The changes in both are functions of temperature and wavelength and outside of the region plotted here their functional form can turn around. It has been found to be optimal to use these changes in a region where both the index and extinction coefficient go in the same direction (e.g., decreasing with more reverse bias). Other regions where they go in opposite directions can also be used, however, the misalignment of the modulator FP dip must then be such that the modulator dip is at a shorter wavelength than the lasing wavelength.

In one aspect, changing the reverse bias to this integrated modulator can increase or decrease the absorption coefficient, and correspondingly also change the refractive index. When those two functions are utilized together, the integrated modulator can have enhanced modulated laser light. FIG. 7 shows the extinction coefficient and index of refraction versus electric field for different temperature ranges. The effect used to provide modulation is the general longer range trends.

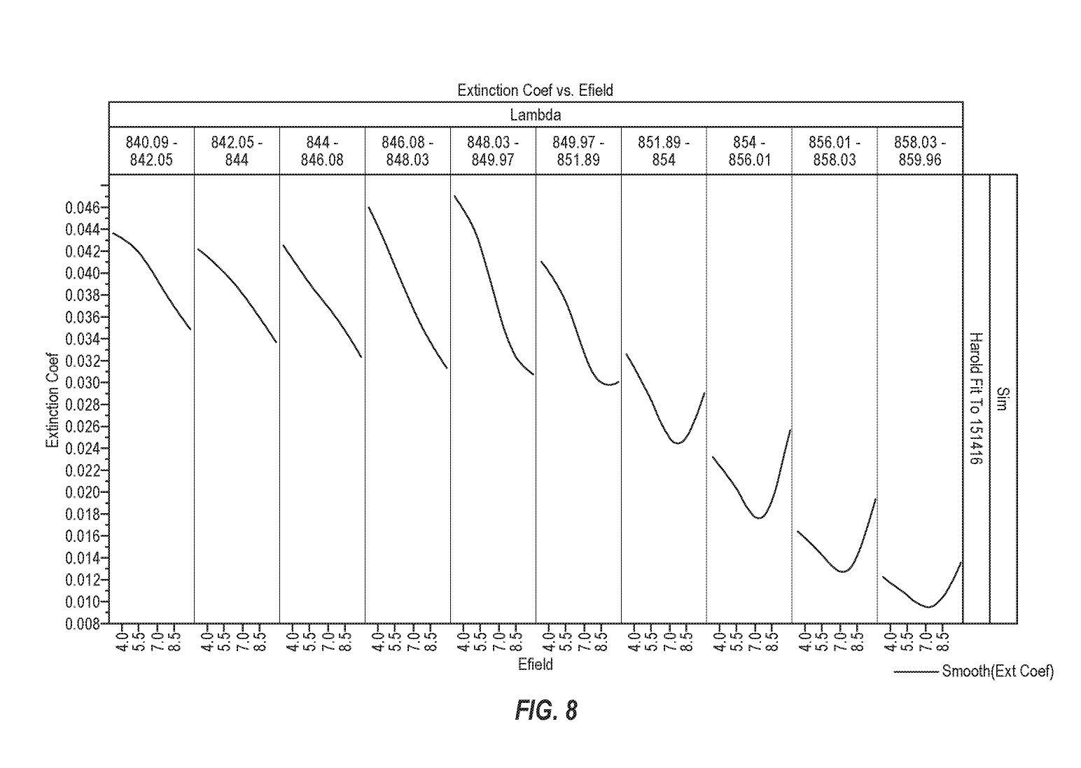

FIG. 8 is the first fit to measured extinction coefficient data on a non-optimized wavefunction deconfinement modulator active region showing the more useful range of downward slopes followed by a region where the slopes are changing signs. Real devices provide smoother curves than the simulations but still show complex shapes. The data can be analyzed by obtaining the extinction coefficient and multiplying it by 4π/wavelength to determine the absorption coefficient. As shown (FIG. 7), when applying more electric field, the index of refraction changes and decreases substantially in the most useful range. The slope of the data lines that goes from the upper left to the lower right, the bottom graphs show a decrease. When measuring the absorption structures, the protocol can use the Kramer's Kronig relations to find the index of refraction coefficient from the extinction coefficient. However, it should be recognized that an optimized structure can include larger effects in changes of the absorption coefficient.

In one embodiment, the VCSEL laser cavity can be coupled to a modulator cavity, with misaligned FP resonances (e.g., FP resonance dips that are not aligned between modulator cavity and primary laser cavity). Also, light reflected back into VCSEL cavity can remain relatively constant to avoid modulating the laser, which can be performed by trading absorption with reflectance. State 1 includes: temperature 80 degrees C.; 0 bias, 3.521 refractive index; 0.0479 extinction coefficient; 0.123 slope efficiency; and 368 gain. In State 1: high index of refraction induced reflectance can be obtained due to FP resonance misalignment being high, and high absorption countering the high index induced reflectance, and the net effect is reduced transmitted light due to both increased reflectance and increased absorption, and the net effect on reflected light is targeted to be of no effect as the reflectance and absorption cancel each other. Note the slope efficiency of only 0.123 mw/ma. The required gain in the quantum wells of the laser is 368/cm. State 2 includes: temperature 80 degrees C.; 3 bias, 3.516 refractive index; 0.0195 extinction coefficient; 0.234 slope efficiency; and 378 gain with 1.617 ER. In State 2: low absorption and low reflection results in high transmission so that the slope is 0.234 mw/ma. Note that the change in required quantum well gain is small, <3% due to the small change in back reflection. This is an example of a condition where a large change in slope efficiency can be achieved with minimal change in back reflection. This reduces intersymbol interference in the eye diagram. The data also shows the calculation of slope efficiency for a VCSEL having an integrated modulator.

Table 1 is an example of a modulator structure for an unchirped modulator where the top emitting surface is at the bottom and the VCSEL (e.g., emitter structure) is adjacent on the top. Orientation reversal is because the layers are listed in the order of epitaxial growth. This device includes 27 pairs of wells.

TABLE 1

| | | Thickness | | | N | P | | | |
|---|---|---|---|---|---|---|---|---|---|
| | | (nm) | | Composition | doping | doping | Index | Ext Coef | |
| 9 | loop | 19.878 | ALGAAS | 0.15 | | 4.00E+18 | | | Compositional ramp to 15% |
| | | 42.142 | ALGAAS | 0.15 | | 4.00E+18 | | | |
| | | 19.878 | ALGAAS | 0.92 | | 4.00E+18 | | | Compositional ramp to 92% |
| | | 48.742 | ALGAAS | 0.92 | | 4.00E+18 | | | AlGaAs |
| | | 19.878 | ALGAAS | 0.24 | | 3E+18 | | | Comp Ramp |
| | | 13 | ALGAAS | 0.24 | | 1E+18 | | | |
| | | 4 | ALGAAS | 0.09 | | 0 | | | Bar comp ramp |
| 27 | loop | 4 | ALGAAS | | | | 3.51619 | 0.0195 | barrier ramp 9-24% |
| | | 5.4 | ALGAAS | | | | 3.51619 | 0.0195 | GaAs Well |
| | | 0 | ALGAAS | | | | 3.51619 | 0.0195 | Dummy layer 24% |
| | | 4 | ALGAAS | | | | 3.51619 | 0.0195 | Barrier ramp 24-9% |
| | | 4 | ALGAAS | 0.24 | | | | | Comp ramp |
| | | 6.97 | ALGAAS | 0.24 | | | | | Bar |
| | | 9.9392 | ALGAAS | 0.24 | 1E+18 | | | | Bar |
| 7 | loop | 19.878 | ALGAAS | 0.15 | 4E+18 | | | | Comp ramp |
| | | 42.142 | ALGAAS | 0.15 | 4E+18 | | | | AlGaAs |
| | | 19.878 | ALGAAS | 0.92 | 3E+18 | | | | Comp ramp |
| | | 48.742 | ALGAAS | 0.92 | 3E+18 | | | | AlGaAs |
| | | 19.878 | ALGAAS | 0.2 | 5E+18 | | | | Comp ramp |
| | | 24.848 | ALGAAS | 0.2 | 5E+18 | | | | |
| | | 19.878 | ALGAAS | 0 | 5E+18 | | | | |

In one aspect, a VCSEL can include a modulator cavity over a laser cavity so as to be integrated therewith. The modulator can be configured to change the refractive index and absorption coefficient, which allows a modulator to be designed where the light reflected back into the laser cavity can remain relatively constant, even while the light coming out of the VCSEL is modulated by the integrated modulator. In one design and operational paradigm, the functionality of modulation with constant back reflection can be obtained by trading off the absorption effects and reflection effects. In State 1 with higher reflectance, a refractive index that causes FP resonance dips of the primary laser cavity and the modulator cavity to be significantly different, there is higher reflectance back into the VCSEL. At the same time the device is configured so it has high absorption from a low bias on the curves (e.g., close to zero bias), so that high refractive index which causes the higher reflectance are aligned and the high absorption are both occurring at the same time. With the higher reflectance and the high absorption, the light is absorbed and/or reflected by the integrated modulator so that less light is emitted out of the device. However, at the same time the FP resonant dip misalignment without significant reverse bias (e.g., no bias) can make the reflectance high. The absorption in the modulator can make the reflectance low, so the combination is less of a change on the reflective light. The net effect on the transmitted light is from both the increased reflection and increased absorption for less light emission. The other state can be low absorption and low reflection for more light emission when more reverse bias is applied to the modulator cavity. When there is more reverse bias it makes absorption low and it reduces the refractive index, and when combined with alignment of the FP resonance dips in the laser cavity and modulator cavity which get closer together, the result is an increase in the laser light emitted from the device (e.g., in part, reduced the reflection) and this results in a high laser light output state.

In one embodiment, to avoid back reflection related effects, constant back reflection design can be used and/or a dual drive can be implemented. In one aspect, variable back reflection can cause fluctuations in photon density in primary laser cavity coupling slowly to the carrier population. In a first option, the variable back reflection can be inhibited by use of constant back reflection by playing the refractive index change and extinction coefficient change off each other so reflection loss due to absorption is substantially equal to the reflection gain due to refractive index change (e.g., more FP resonance dip mismatch between the laser and modulator cavities).

In one embodiment, the configuration of the laser device can be obtained by varying the alignment of the FP dips. The structure has two coupled cavities each with an FP dip. As the alignment of the FP dip changes the reflection/transmission and absorption all change. By having the misalignment in the right direction, the electric field induced absorption/index result in a synergistic change in transmission. If misaligned, the other way they work against each other. For an effect where more reverse bias causes less absorption and a lowered index, the modulator dip must be longer than the laser dip. Then as more bias is applied, the FP dips get closer to alignment (e.g., by reducing the wavelength of the modulator FP dip) increasing transmission, and the absorption is reduced increasing transmission. Transmission is affected synergistically by both refractive index change and extinction coefficient change and back reflection is compensated to remain constant.

In the first option, the laser can be designed for this operational paradigm. For example, the way the FP resonance dips are offset can be designed by the FP resonance dips of the modulator to be longer than the FP resonance dips of the primary laser cavity. In one aspect, the modulator can be driven with varying bias with the primary laser cavity being driven with direct current.

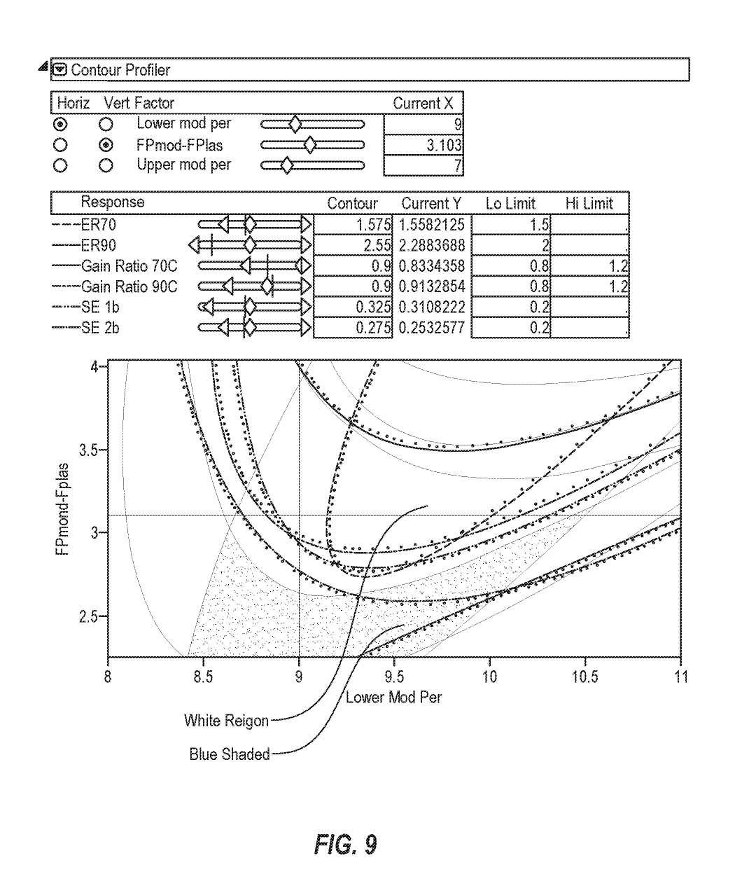

In a second option, the variable back reflection can be compensated for by use of a dual drive. This can include driving the gain in the quantum wells in the integrated laser so that when the reflectivity of the modulator back into the laser decreases (increased transmission) and the absorption in the modulator decreases, the photon density does not change even if the back reflection effects of the index and absorption do not cancel because the gain is increased or decreased in a manner to compensate for the non-cancelling of the back reflection change so that the photon density remains constant. The quantum wells in the laser cavity provide this adjusted gain and are driven separately from the modulator cavity, which results in a dual drive implementation. This option can keep the photon density in the primary laser cavity substantially constant by driving both the gain in the quantum wells in the primary laser cavity and absorption and index of refraction of the quantum wells in the modulator, where both the primary laser cavity and modulator are both driven at the same time. By keeping the photon density in the primary laser cavity constant coupling to the relaxation oscillation of the laser does not occur which is of primary importance because the relaxation oscillation is relatively slow. Thus, when the device drives both the quantum wells in the primary laser cavity and in the modulator, the device can keep the photon density in the primary laser cavity substantially constant even if the compensating mechanisms are not working optimally. This avoids coupling to the relaxation oscillation. With dual drive, the RC parasitic of the primary laser cavity and the carrier relaxation time (e.g., short), can result in two different signals with different amplitudes to the modulator versus the primary laser cavity. Dual drive allows for variations in the structure, wavelength and temperature. At different temperatures and wavelengths the relative effect of the absorption change and index change on back reflection are different, so that this ability to keep the photon density constant despite the incomplete cancellation of the effect of index change and absorption change on the back reflection is useful to prevent coupling to the relaxation oscillation of the laser. FIG. 9 shows that the small delta in required gain for the two states could be accommodated by driving the gain in the active region, and thus keeping the photon density constant completely avoiding coupling to the relaxation oscillation of the laser. While this shows the optional use of dual drive only providing slight benefit, the conditions for this simulation were optimized to have nominally constant back reflection. In cases where the back reflection has a large change then dual drive can be used to compensate for it. The problem with dual drive is the added complexity combined with the relatively large parasitics (e.g., RC and carrier relaxation) of the primary laser it is difficult but practical to minimize these.

In one embodiment, the relaxation oscillation frequency of the laser is designed to be a low value so that coupling to it can be minimized To minimize the relaxation oscillation frequency of the laser, quantum wells made from low differential gain material such as GaAs, as compared to InGaAs for example can be used. Another example is driving the laser with either low enough current of high enough current such that the differential gain is reduced. This reduces the ROF dramatically compared to the half the data rate and helps dramatically in keeping the eye open.

In one embodiment, the damping of the laser is designed to be high so that the relaxation oscillation becomes unimportant in the response. One example of conditions where this occurs is at high current drives, though it can be designed into the device with high reflectance and low required gain. Combining this with dual drive limits the required speed of the dual drive to approximately the optical −3 dB point of the laser.

In one embodiment, the dual drive is used in combination with the low relaxation oscillation frequency. In this case the RC and carrier relaxation times applied by the second drive on the active region must only be less than 1/(2*pi*ROF) then the dual drive can contribute to the eye opening. A low ROF helps in this regard.

FIG. 9 shows data for a transmission matrix simulation. The data shows an example of allowable design in white for a 70-90° C. temperature range. The lower modulator mirror has nine periods, and the upper modulator mirror has seven periods. The modulator FP resonance minus the primary laser FP resonance is equal to about 3.1 nm. The white region shows the allowed design range for gain ratio (ratio of primary laser gains for the two states) of 1+/−0.2, and minimum extinction ratio 1.5 (ratio of emitted light in the two states). The contour intersection shows a particular value for design. Here, there is misalignment between the FP resonance dips of the modulator cavity compared to the primary laser cavity. The white area is a range that provides an exemplary operating environment. The contours are defined with ER2 and ER1 as extinction ratios at different temperatures that can be achieved. The white area generally gives about a 2 to 1 or better extinction ratio at 90° C., 1.5 to 1 or better at 70° C. and provides an operational temperature range of 20° C. This allows a design with a broad temperature range that is suitable for use in a data center that may not have good temperature control and allows for easy temperature control with a resistive heater. The gain ratio in the quantum wells in the two states—high state or low state—can be set close to one or the ratio can be one when optimized. Note that the limits on the gain ratio 0.8-1.2 substantially limit the operational parameters of the device at 70° C. (blue shading). Dual drive can be used to eliminate this restriction expanding the allowable range of parameters and temperature. Even inside this range the device can benefit from dual drive as the eye will have even less closure due to intersymbol interference.

In one example, the FP resonance dip splitting between the primary laser cavity and modulator cavity can be between about 2.5 and up to about 4. The splitting between about 2.5 and up to about 4.0 provides 1.5 nanometers of splitting range that can be controlled using for example MOCVD or MBE.

In one example, the temperature range of the device simulated in the above-recited State 1 and State 2 is only 20° C. which while it is substantially greater than the allowable temperature range of a band edge stark shift modulator, it still can be improved upon.

Table 2 shows a similar structure to Table 1 except the quantum well thickness is varied (chirped). In this case there are two primary quantum well thicknesses instead of one. The ratio of the number of thick wells to thin wells is 1:3. For two well thicknesses a ratio of about this amount (e.g., 1.3+/−5%, 10%, or 20%) provides superior performance.

TABLE 2

| | | Thick | | Composition | Extinction | | | |
|---|---|---|---|---|---|---|---|---|
| | | nm | | or index | coef | n doping | P doping | |
| 7 | loops | 19.878 | ALGAAS | 0.15 | | | 4.00E+18 | Comp ramp |
| | | 42.142 | ALGAAS | 0.15 | | | 4.00E+18 | AlGaAs |
| | | 19.878 | ALGAAS | 0.92 | | | 4.00E+18 | Comp ramp |
| | | 48.742 | ALGAAS | 0.92 | | | 4.00E+18 | AlGaAs |
| | | 19.878 | ALGAAS | 0.24 | | | 3E+18 | {Comp ramp |
| | | 7.25 | ALGAAS | 0.24 | | | 1E+18 | |
| | | 4 | ALGAAS | 0.09 | | | 0 | Comp ramp |
| | | | | | | | | barrier ramp 9-24 |
| 7 | loops | 4 | ALGAAS | 3.47 | 0.0028 | | | % {CR} |
| | | 5.6 | ALGAAS | 3.47 | 0.0028 | | | GaAs Well Thick |
| | | 0 | ALGAAS | 3.47 | 0.0028 | | | Dummy layer 24% |
| | | | | | | | | Barrier ramp 24-9% |
| | | 4 | ALGAAS | 3.47 | 0.0028 | | | {CR} |
| | | | | | | | | barrier ramp 9-24 |
| | | 4 | ALGAAS | 3.47 | 0.0028 | | | % {CR} |
| | | 5 | ALGAAS | 3.47 | 0.0028 | | | GaAs Well thin |
| | | 0 | ALGAAS | 3.47 | 0.0028 | | | Dummy layer 24% |
| | | | | | | | | Barrier ramp 24-9% |
| | | 4 | ALGAAS | 3.47 | 0.0028 | | | {CR} |
| | | | | | | | | barrier ramp 9-24 |
| | | 4 | ALGAAS | 3.47 | 0.0028 | | | % {CR} |
| | | 5 | ALGAAS | 3.47 | 0.0028 | | | GaAs Well thin |
| | | 0 | ALGAAS | 3.47 | 0.0028 | | | Dummy layer 24% |
| | | | | | | | | Barrier ramp 24-9% |
| | | 4 | ALGAAS | 3.47 | 0.0028 | | | {CR} |
| | | | | | | | | barrier ramp 9-24 |
| | | 4 | ALGAAS | 3.47 | 0.0028 | | | % {CR} |
| | | 5 | ALGAAS | 3.47 | 0.0028 | | | GaAs Well thin |
| | | 0 | ALGAAS | 3.47 | 0.0028 | | | Dummy layer 24% |
| | | | | | | | | Barrier ramp 24-9% |
| | | 4 | ALGAAS | 3.47 | 0.0028 | | | {CR} |
| | | 4 | ALGAAS | 0.24 | | | | {CR} |
| | | 7.25 | ALGAAS | 0.24 | | | | Bar |
| | | 10 | ALGAAS | 0.24 | | 1E+18 | | Bar |
| 4 | 9 | 19.878 | ALGAAS | 0.15 | | 4E+18 | | {CR} |
| | | 42.142 | ALGAAS | 0.15 | | 4E+18 | | AlGaAs |
| | | 19.878 | ALGAAS | 0.92 | | 3E+18 | | {CR}{PR} |
| | | 48.742 | ALGAAS | 0.92 | | 3E+18 | | AlGaAs |
| | | 19.878 | ALGAAS | 0.2 | | 5E+18 | | {CR}{PR}cool before |
| | | 24.848 | ALGAAS | 0.2 | | 5E+18 | | |
| | | 19.878 | ALGAAS | 0 | | 5E+18 | | |

The following two states is from an example calculation using the transmission matrix method showing a nominally constant gain in the two states as well as a ratio of slope efficiencies of 1.6. State 1 includes: temperature 100 degrees C.; 0 bias, 3.522 refractive index; 0.0352 extinction coefficient; 0.115 slope efficiency; and 398 gain. State 2 includes: temperature 100 degrees C.; 3 bias, 3.512 refractive index; 0.01836 extinction coefficient; 0.186 slope efficiency; and 401 gain with 1.617 ER.

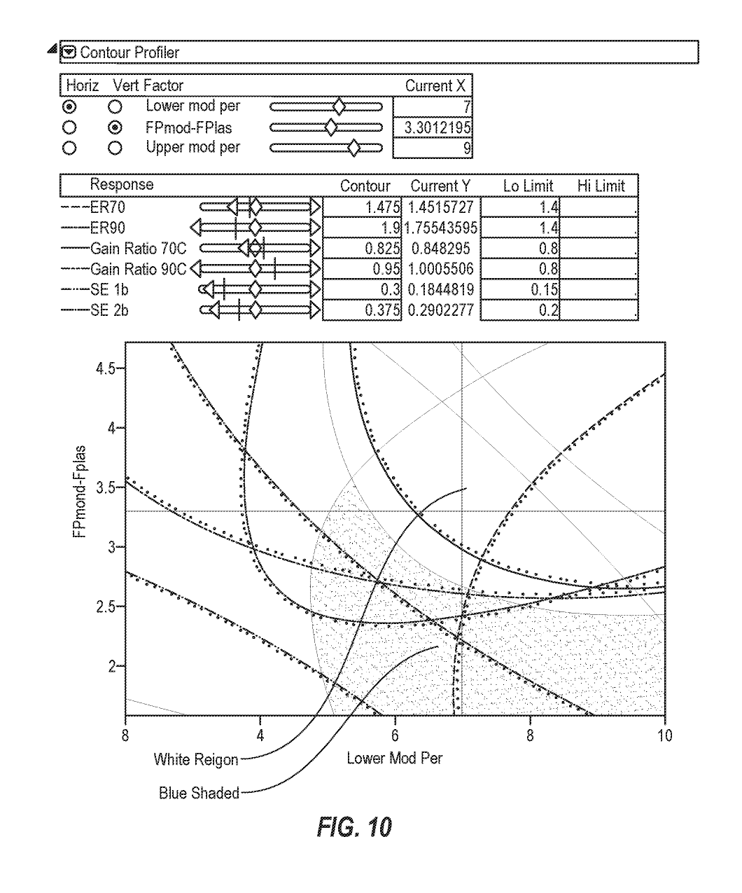

FIG. 10 shows the allowable ranges (white region) for this modulator to operate between 70 C and 105 C. Note once again the allowable parameter space can be improved dramatically by dual drive as the blue shaded restriction from the gain ratio can be eliminated. Again, even inside this range the device can benefit from dual drive as the eye will have even less closure due to intersymbol interference.

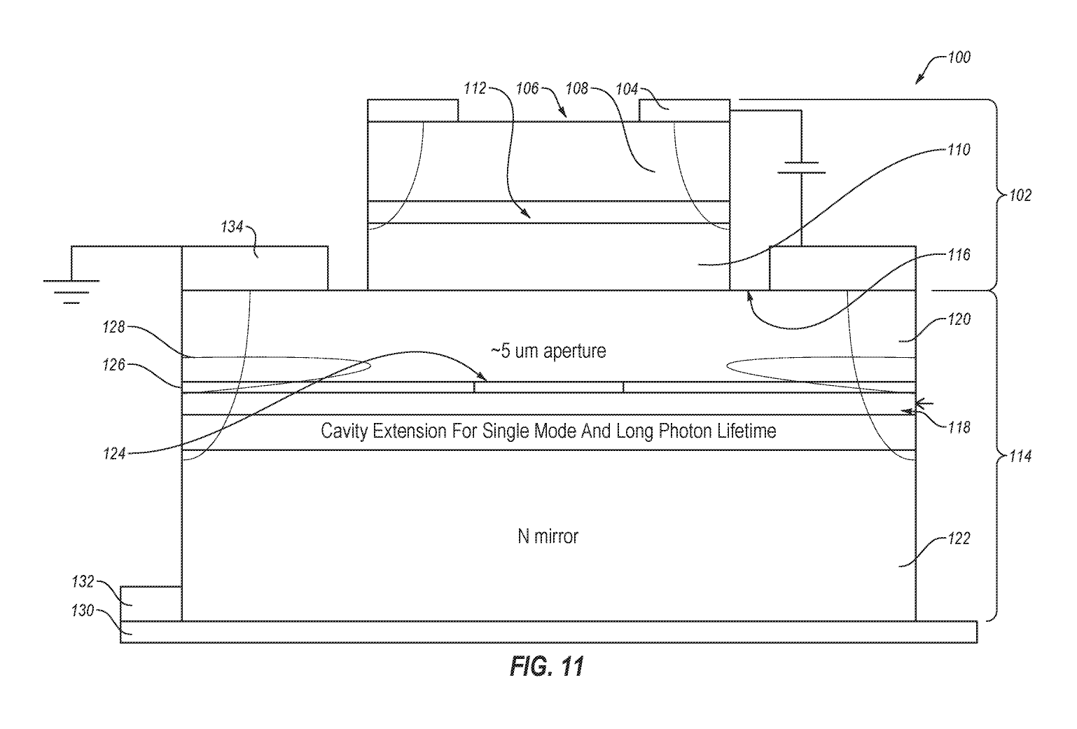

FIG. 11 includes a schematic diagram of an embodiment of a VCSELs having the integrated modulator. It should be noted that this is an example, and the layout of the VCSEL having the integrated modulator may be modified as known in the art. Also, the VCSEL can have the various regions, layers, and features common in VCSELs.

As can be seen in FIG. 11, on the top of the VCSEL 100 is the modulator section 102 that has a high speed low capacitance contact 104, which can be annular that provides a small aperture 106 for light emission. The aperture 106 can have a small diameter. The modulator section 102 can include a top modulator mirror 108 and a bottom modulator mirror 110 that bound the top and bottom of the modulator cavity 112. The modulator cavity 112 can include the modulator quantum wells, and which can be configured as an EO/EA layer. The modulator cavity 112 is biased for the change in refractive index and absorption modulation, where the bias is reverse bias, which provides a low capacitance. The top modulator mirror 108 above the modulator cavity 112 having the quantum well EO/EA layers can have high doping. The high doping in the top modulator mirror 108 can be doped in an amount to keep its resistance down. Additionally, the top modulator mirror 108, modulator cavity 112, and/or bottom modulator mirror 110 can individually or in combination have a thickness that provides a lower capacitance across the active region in the modulator cavity 112. The configuration and dimensions of the top modulator mirror 108, modulator cavity 112, and/or bottom modulator mirror 110 can be modulated to vary speeds, and may be modulated to increase or decrease speeds. The variations in configurations can allow for about 50 to about 100 gigahertz VCSELs. The modulator section 102 can be a mesa configuration. The modulator section 102 can be on a base section 114 that has a shoulder region 116 lateral of the mesa-shaped modulator section 102. The base section 114 includes the primary lasing cavity 118 with a top lasing mirror 120 over the primary lasing cavity 118 and a bottom lasing mirror 122 under the primary lasing cavity 118. The primary lasing cavity can be configured with a single mode or multi-modes. Between the primary lasing cavity 118 and the top lasing mirror 120, an aperture 124 can be formed as is known in the art, such as forming an annular oxide member 126 to define the aperture 124. In one aspect, the aperture can be about 5 microns, which can be used so that the primary laser cavity 112 is single mode and results in a single mode device. Various mode selective techniques have been demonstrated such as selective loss, gratings, cavity extensions or the like which may be implemented also.

The base section 114 can include a cavity extension region 136 between the primary lasing cavity 118 and bottom lasing mirror 122. The cavity extension region 136 can be used to facilitate a single mode with long photon lifetime. However, in a multimode embodiment, the cavity extension region 136 can be omitted. The cavity extension region 136 can be AlAs to enhance thermal conduction or another composition. The cavity extension can be AlGaAs, and may be ¼+n half waves thick, where n is a whole number.

The dimension of the modulator section from top to bottom can vary, such as from about 2 to 5 microns, or at about 2.7 microns or about 5.7 microns, or variation thereof.

The shoulder region 116 of the base section 114 can include a AC grounded contact 134, which can also be annular as shown.

In one example, any standard VCSEL having a primary laser cavity 112 with a top lasing mirror 120 and bottom lasing mirror 122 can be used as a base section 114 for forming the modulator section 102 thereover. That is, the modulator section 102 can be grown over the base section 114 by any standard manufacturing process. The modulator section 102 and base section 114 provide a coupled cavity.

In one aspect, the base section 114 can include any features included in a VCSEL, such as implant regions lateral of the aperture 124 and/or quantum wells of the primary laser cavity 118, which implant regions are shown by the region of 128.

The bottom lasing mirror 122 can be on a suitable substrate 130, and a high speed substrate contact 132 can be included when the VCSEL 100 is configured with dual drive.

In one embodiment, the VCSEL having the integrated modulator can be a full EPI structure.

In one example, upon ending the VCSEL growth (e.g., top lasing mirror), the EPI structure can be continued by growing the modulator section thereon. In one aspect, the subject matter of U.S. Pat. No. 7,983,572 can be incorporated here by specific reference. Specifically, the FIGS. 1, 2, 3, and 4 and the descriptions thereof are incorporated herein by specific reference and can be used and modified for the laser having the integrated modulator described herein. The generic features of U.S. Pat. No. 7,983,572 can be modified with the particularities described herein in order to facilitate operation of the laser and modulation of the laser light with the integrated modulator.

In one aspect, it is noted that operating a lower fields in the modulator and implementing wavefunction deconfinement as described herein can enhance modulation. At the low field, the electron and/or hole wavefunction can be mostly moved out of the primary quantum wells of the modulator. This operation takes advantage of previously unfavorable parasitic effects on Stark shift modulators, and using the parasitic effect of wavefunction deconfinement to modulate the laser light. The parasitic effect is used as a dominant effect by designing the wells so it can be used as a modulator at low applied electric fields.

In one aspect, the mode structure of the laser can be single mode, or multimode, and any polarization. A single fundamental mode is the preferred embodiment.

In one aspect, the effective cavity length of the modulator is kept short using an intentionally large index difference between the low index layers and high index layers of the mirrors so the penetration depth into the mirror is minimized resulting in the index change provided by the active region, 118, causing the maximum shift in the modulator FP dip.

To drive the device optimally without dual drive, the DC bias on the modulator, the amplitude of the modulated signal, and the temperature must be optimized together. A feedback circuit which monitors the quality of the modulation (eye opening) is useful in optimizing these variables. There will be substantial ranges of these parameters which will provide adequate eye opening so it is not necessary to be perfectly optimized on each parameter. If dual drive is used the second drive amplitude, and the primary laser DC current need to be added as controlled variable. Pre-emphasis can be used on both the primary and secondary drive to achieve higher speeds.

In one aspect, the laser with integrated modulator can include a heating element therein. The heating element can be used to provide an increased temperature operation range, such as from −40 to 120 degrees C. Also, even a 30 degree C. temperature range can be useful. In reference back to FIG. 2, a dip is shown between the quantum wells which is the secondary well. The secondary quantum wells can be generated by programing ramps into the mass flow controller. However, other structures can be used. In any event, the structure is designed so that the wavefunctions deconfine with a relatively small electric field, and when the wavefunctions are confined there is strong overlap (a high overlap) between the electron wavefunction and hole wavefunction. For example, operation shown in FIG. 5 shows the modulating effect from electron deconfinement and hole deconfinement. While a single well pair can be used, multiple well pairs can also be used, such as two or more well pairs. See for example Table 1.

The following equation shows the relationship between the lower mirror, gain region, and top mirror having the integrated modulator, and equation for calculating slop efficiency.

η=E*T*ηᵢ/(2−RL−R)

η is slope efficiency; ηᵢ, is internal efficiency; RL is lower mirror reflectance, R is upper mirror reflectance; T is upper mirror/modulator transmission; and E is photon energy. The top mirror is part of the modulator, which has properties of reflection (R), and transmission (T), and absorption (A). The configuration includes a coupled cavity. There is the gain region between the lower mirror and top mirror. The slope efficiency can be calculated by the equation.

The following equations show the dual drive and constant back reflection constraining equations.

RL*G*R=1 Eq1:

R+T+A=1. Eq2:

The variables are defined as above with A is the upper mirror/modulator absorption, and G is the active region gain.

Dual drive is implemented by varying R and G simultaneously so Eq1 is satisfied. With constant back reflection, T=1−R−A, R is constant, then T varies with absorption. This can result in keeping R constant and balancing the effect on reflection of refractive index and absorption off each other to achieve operation.

In one example with the constraining equations, Eq1 reflection of the lower mirror times the gain of the active region and the reflection of the upper mirror has to equal one for the laser to lase. If the lower mirror is 99% reflective and upper mirror is 99% reflective, then gain has to be: (1/0.99)*0.99, so that the Eq1 equals 1 and then the laser lases.

In an example of the dual drive, there is varying of the reflection on the top mirror and the gain simultaneously so Eq1 is satisfied. Both equations are always satisfied, and when there is variation in the reflection there is also variation in the transmission.

Table 3 illustrates a sample of simulated data for using dual drive to enhance the extinction ratio (ER).

TABLE 3

| Fpmod-FP | | Lower | Upper | | | | | | | | |
|---|---|---|---|---|---|---|---|---|---|---|---|
| laser state1 | | mod | mod | Efield | Index | | SE | | | | Gain |
| 97 C. (nm) | Temp C. | per | per | V/um | delta | Ext Coef | mw/ma | Gain/cm | State | ER | ratio |
| 4.5 | 97 | 3 | 9 | 4.2 | 0 | 0.017 | 0.294 | 522 | low | | |
| | 97 | 3 | 9 | 12.7 | −0.022 | 0.0037 | 0.582 | 536 | high | 1.979592 | 1.02682 |
| | 62 | 3 | 9 | 4.2 | 0 | 0.022 | 0.261 | 562 | low | | |
| | 62 | 3 | 9 | 12.7 | −0.0094 | 0.007 | 0.434 | 480 | high | 1.662835 | 0.854 |
| 2.6 | 97 | 3 | 11 | 4.2 | 0 | 0.017 | 0.271 | 905 | low | | |
| | 97 | 3 | 11 | 12.7 | −0.022 | 0.0037 | 0.702 | 1447 | high | 2.6 | 0.62 |

The data shows that at 97 degrees C. the gain ratio is ˜1, and the ER is ˜2, which is due to trading the effect of the refractive index delta and extinction coefficient being modulated with respect to each other to keep back reflected light constant, and modulate the laser light output. For 62 degrees C. the numbers are acceptable. In the bottom 2 rows, instead of optimizing gain ratio, the ER is optimized. In this case the gain can be modulated using dual drive. The current is increased so that the photon density in the primary cavity remains constant despite the increase in slope efficiency. The optimal current modulation amplitude for a particular device can be determined experimentally. There can be a benefit with a higher extinction ratio (e.g., 2.6), however, such a higher extinction ratio can require using dual drive. In one aspect, it can be beneficial to design the device for nearly constant reflectivity. Alternately, the device can be designed for maximum extinction ratio, and then dual drive is utilized. The high extinction ratio can overcome problems associated with large jitter, large interference, and eye closure.

In view of the foregoing, wavefunction deconfinement modulation allows broader wavelength range and hence broader temperature range operation of the laser. Use of constant back reflection playing off index change and extinction coefficient change works synergistically to modulate the transmission of laser light. Dual drive can be used to compensate for back reflection changes to keep the photon density in the primary cavity constant and thus avoid coupling to the relaxation frequency of the laser.

In one embodiment, the present technology omits or excludes direct modulated coupled cavity VCSELs, Silicon Photonics devices with Mach Zehnder (MZ) interferometers, ring resonators in Silicon Photonics and/or Lithium niobate MZ inferometers. In one aspect, the present technology excludes an external modulator.

In one aspect, the present disclosure incorporates by specific reference the subject matter of U.S. Provisional Application Ser. No. 61/986,326 filed Apr. 30, 2014, and U.S. application Ser. No. 14/698,180 filed Apr. 28, 2015, and U.S. Provisional Application Ser. No. 61/923,428 filed Jan. 3, 2014, and U.S. application Ser. No. 14/589,392 filed Jan. 5, 2015 which subject matter includes the disclosure related to the electro-optic modulator, which electro-optic modulator described therein can be utilized as the integrated modulator in the current devices and methods described herein. The graphene intra-cavity absorber can be configured and used as the integrated modulator as described herein.

Previously, complex quantum wells have been show with the electron remaining confined in a larger overall quantum well, but the hole wavefunction moves around in the sub-portions of that well. However, this is not hole deconfinement because the hole wavefunction remains in this well and thereby is not deconfined from the well. Also, such hole wavefunction modulation has not been conducted along with electron deconfinement at the same time. Now, hole deconfinement by itself can be used as described herein. Also, hole deconfinement may be used with electron deconfinement as described herein. Accordingly, changing the overlap integral of the hole wavefunction and electron wavefunction can be used for modulation.

In one embodiment, a method of modulating a laser device having an integrated modulator can include: emitting laser light from a laser cavity having quantum wells; passing the laser light through a modulator cavity having at least one modulator quantum well that is coupled with the primary laser cavity and integrated with the laser device; and biasing the modulator cavity so as to deconfine electron and/or hole wavefunctions in the at least one modulator quantum well of the modulator cavity such that the refractive index and absorption of the modulator cavity changes to modulate the laser light passing through the modulator.

In one embodiment, a method of modulating a laser device having an integrated modulator can include: emitting laser light from a laser cavity having quantum wells; passing the laser light through a modulator cavity having at least one modulator quantum well that is coupled with the primary laser cavity and integrated with the laser device; and applying bias to the modulator cavity so as to substantially increase the spatial volume occupied by the electron wavefunction and/or hole wavefunction from the at least one modulator quantum well of the modulator cavity such that the refractive index and absorption of the modulator cavity changes to modulate the laser light passing through the modulator.

In one embodiment, a method of modulating a laser device having an integrated modulator can include: emitting laser light from a laser cavity having quantum wells; passing the laser light through a modulator cavity having at least one modulator quantum well that is coupled with the primary laser cavity and integrated with the laser device; and using an applied field in a PIN configuration so that the modulator cavity modifies the spatial extent and position of the electron and hole wavefunctions so that the modulator cavity has an absorption change and refractive index change sufficient to achieve modulation of the laser light.

In one embodiment, a method of modulating a laser device having a resonant integrated modulator can include: emitting laser light from a laser cavity having quantum wells; passing the laser light through a modulator cavity having at least one modulator quantum well that is coupled with the primary laser cavity and integrated with the laser device; and providing a defined electric field to the modulator cavity so that the index of refraction and absorption coefficient both decrease, then a nominal independent Fabry Perot resonance of the modulator cavity is longer wavelength than a Fabry Perot resonance of the laser cavity.

In one embodiment, the method of modulating a laser device having a resonant integrated modulator can include: emitting laser light from a laser cavity having quantum wells; passing the laser light through a modulator cavity having at least one modulator quantum well that is coupled with the primary laser cavity and integrated with the laser device; and providing a defined electric field to the modulator cavity so that one of the index of refraction or absorption coefficient increases and the other of the index of refraction or absorption coefficient decreases, then a nominal independent Fabry Perot resonance of the modulator cavity is shorter than a Fabry Perot resonance of the laser cavity.

In one aspect, the modulator cavity has an optically active region that has the change of refractive index and change of absorption. In one aspect, more than one modulator quantum well thickness in the modulator cavity is varied thereby increasing the operational temperature range. In one aspect, one or more modulator quantum well thickness in the modulator cavity is varied thereby increasing the operational temperature range. In one aspect, the method of modulation can include at least partially containing the deconfined electron and/or hole wavefunctions in a secondary modulator well region adjacent to a primary modulator well region, the primary modulator well region containing the at least one modulator quantum well.

In one embodiment, the design and manufacture can be modulated to obtain the laser device having a resonant integrated modulator that can be operated in accordance with the methods. In one aspect, the secondary modulator well region is designed to minimize the reduction of a band edge with an applied field. In one aspect, the secondary modulator well region includes a “V” shaped secondary modulator quantum well. In one aspect, the secondary modulator well region includes a non-square shaped secondary modulator quantum well.

In one aspect, the method can include minimizing a reduction of the band edge. In one aspect, the method can include minimizing a change in back reflection during lasing and/or modulation of the laser light. In one aspect, the method can include minimizing a change in back reflection during lasing and/or modulation of the laser light wherein the laser device having the integrated modulator has a design obtained from a transmission matrix method.

In one aspect, the integrated modulator is a resonant integrated modulator that includes one or more resonant cavities. In one aspect, the modulator quantum wells include two or more different modulator quantum well structures. In one aspect, the modulator quantum wells include two or more different modulator quantum well structures, wherein at least one modulator quantum well structure absorbs a shorter wavelength of laser light than other modulator quantum well structures. In one aspect, the different modulator quantum well structures include variations in width of the modulator quantum wells. In one aspect, the different modulator quantum well structures include variations in compositions of the modulator quantum wells. In one aspect, the different modulator quantum well structures include variations in wavelengths that are absorbed by the modulator quantum wells.

In one embodiment, the laser device having a resonant integrated modulator can have different configurations. In one aspect, the integrated modulator can include a first set of modulator quantum wells that absorb a first wavelength and a second set of modulator quantum wells that absorb at a different second wavelength. In one aspect, the integrated modulator can include a first set of modulator quantum wells that absorb a short first wavelength and a second set of modulator quantum wells that absorb at a different long second wavelength. In one aspect, the integrated modulator can include a first set of modulator quantum wells that absorb a range of short first wavelengths and a second set of modulator quantum wells that absorb a range of different long second wavelengths. In one aspect, the integrated modulator can include a first set of modulator quantum wells that absorb a range of short first wavelengths and a second set of modulator quantum wells that absorb a range of different long second wavelengths, a ratio of the first set of modulator quantum wells to the second set of modulator quantum wells (first set : second set) being greater than 1.8:1. In one aspect, the modulator cavity has an optically active region that has the change of refractive index and change of absorption. In one aspect, the primary laser cavity and modulator cavity are in integrated semiconductor regions, such as by epitaxial integration. In one aspect, the modulator cavity is in a mesa region coupled to a base region, the base region having a laterally extending shoulder region from the mesa region.

In one embodiment, operation of the laser device having a resonant integrated modulator can be changed to obtain different modulation parameters. In one aspect, the method can include operating the laser device to have greater than 50 GHz bandwidth. In one aspect, the method can include operating the laser device to have greater than 100 Gb/s. In one aspect, the method can include tuning resonance of the modulator cavity about the lasing wavelength by changing the refractive index and changing the absorption. In one aspect, the method can include changing the refractive index and changing absorption can cooperatively maintain back reflection into the laser cavity to be substantially constant. In one aspect, the method can include increasing back reflection caused by a refractive index shift and simultaneously decreasing back reflection caused by increased absorption in the modulator cavity. In one aspect, the method can include decreasing back reflection caused by a refractive index shift and simultaneously increasing back reflection caused by decreased absorption in the modulator cavity. In one aspect, the method can include operating the laser device so that the modulator cavity causes a low slope efficiency, and the modulator cavity has high absorption of the laser light. In one aspect, the method can include operating the laser device so that the Fabry Perot resonance of the modulator cavity is detuned from the lasing wavelength in order to enhance back reflection, wherein the enhanced back reflection is sufficient enough to maintain back reflection from back reflection that is lost due to absorption in the modulator cavity. In one aspect, the method can include operating the modulator cavity to have high absorption and high reflection in an absorption state and then to have low absorption and low reflection in a transmission state, which is performed with substantially constant total back reflection. In one aspect, the method can include implementing dual drive to the laser device for the modulator cavity and laser cavity. In one aspect, the method can include modulating overlap integral of the electron wavefunction and hole wavefunction by applying reverse bias of the modulating cavity so as to substantially deconfine the electron and/or hole wavefunctions.

In one embodiment, the laser cavity of the laser device having a resonant integrated modulator can have different configurations. In one aspect, the laser cavity includes a long photon lifetime low ROF laser. In one aspect, the laser cavity includes a distributed feedback laser. In one aspect, the device can be configured so that the modulator resonance band does not coincide with the lasing wavelength of the laser cavity. In one aspect, the modulator cavity is in a resonant cavity. The laser device can be a VCSEL or edge emitter.

In one embodiment, the temperature can be modulated to obtain improve operation and light modulation. In one aspect, the method can include operating a heating element associated with the laser device to heat the laser cavity and modulator cavity. In one aspect, the heating element can provide a temperature range of 150 degrees C. in the laser device. In one aspect, the environment where the laser device is operating can include a temperature range from −40 to 110 degrees C.

In one embodiment, the method of can include implementing a parasitic effect on a Stark shift band edge to implement wavefunction deconfinement in the modulator well of the modulator cavity. In one aspect, the method can include implementing wavefunction deconfinement in the modulator cavity to modulate the laser light. In one aspect, the method can include providing a low reverse bias to the modulator cavity. In one aspect, the method can include decreasing wavefunction overlap so as to reduce absorption in the modulator cavity. In one aspect, the method can include decreasing wavefunction overlap so as to reduce absorption in the modulator cavity by decreasing a Stark shift of the band edge in the modulator cavity. In one aspect, the method can include operating the laser device so that an applied electrical field causes the electrons and/or hole wavefunctions to mostly reside outside of the primary modulator quantum well region.

In one embodiment, parameters of the modulator can be modified for intended uses. In one aspect, a secondary modulator quantum well region has a wider band gap with larger dimensions compared to a primary modulator quantum well, wherein the secondary modulator quantum well region is configured to at least partially retain the wavefunctions under higher applied bias. In one aspect, a secondary modulator quantum well region is designed so that absorption resulting from electron and hole wavefunction overlap occurs at a significantly shorter wavelength than the wavelength of the laser light. In one aspect, the secondary modulator quantum well region having quantum wells separated by barrier layers, the barrier layers between quantum wells having a compositional ramp and band offsets so as to reduce classic band edge reduction of the Stark Shift. In one aspect, the secondary modulator quantum well region has triangular shaped quantum wells compared to the primary modulator quantum well region having substantially square shaped quantum wells. In one aspect, the secondary modulator quantum well region has quantum wells shaped differently compared to the primary modulator quantum well region square shaped quantum wells so that as bands tilt the energy level does not significantly decrease. In one aspect, the modulator cavity includes an electro-absorption modulator. In one aspect, the modulator cavity includes at least two quantum wells with a secondary quantum well therebetween.

In one aspect, the laser cavity emits wavelengths over at least a 3 nm range or higher range. In one aspect, the laser light emitted from the laser cavity has a wavelength of from about 820 nm to about 880 nm. In one aspect, the laser light emitted from the laser cavity has a wavelength of from about 840 nm to about 860 nm.

In one embodiment, the bias provided to the modulator cavity can be optimized. In one aspect, the operation can include implementing from 3 volts of amplitude for reverse biasing the modulator cavity. In one aspect, the operation can include: applying more reverse bias to the modulator cavity to reduce absorption; and applying less reverse bias to the modulator cavity to increase absorption, wherein the laser light is modulated by the change in reverse bias. These steps can be repeated to modulate the laser.

In one embodiment, the laser device can be configured so that Fabry Perot resonance dips can be more closely aligned or less closely aligned by application of the reverse bias to the modulator cavity, wherein: more closely aligned Fabry Perot resonance dips results in less absorption in the modulator cavity; and less closely aligned Fabry Perot resonance dips result in more absorption in the modulator cavity.

In one aspect, with more reverse bias, the Fabry Perot resonance dips become more aligned which results in less absorption in the modulator cavity; and with no or less reverse bias, the Fabry Perot resonance dips are unaligned which results in more absorption in the modulator cavity. In one aspect, the Fabry Perot resonance dips in the modulator cavity are longer than and offset from Fabry Perot resonance dips in the laser cavity when no bias is applied to the modulator cavity.

In one embodiment, operation of the laser cavity and modulator can be done separately by driving the laser quantum wells separately from the modulator quantum wells. In one aspect, the operation can include maintaining photon density in the laser cavity to be substantially constant by driving gain in the laser quantum wells and the losses caused by the modulator separately at the same time. In one aspect, the operation can include driving the modulator cavity with varying bias and driving the laser cavity with constant bias. In one aspect, the operation can include driving the modulator cavity with alternating current and driving the laser cavity with direct current. In one aspect, the operation can include increasing gain in the laser quantum wells of the laser cavity so that photon density does not decrease, and where reflectivity of the top modulator mirror does not decrease.

In one embodiment, a laser device can have the features described herein in order to be operated as described herein to modulate the laser light from the laser cavity with the integrated modulator. In one aspect, the laser device includes: a bottom lasing mirror; a laser cavity having laser quantum wells over the bottom lasing mirror; an aperture above the laser cavity; a top lasing mirror over the aperture; a bottom modulator mirror over the top lasing mirror; a modulator cavity over the bottom modulator mirror; a top modulator mirror over the modulator cavity; a modulator contact on top of the top modulator mirror; and a AC ground contact connected to the top lasing mirror. In one aspect, the laser device includes an aperture that is about 5 microns.

In one aspect, the laser device can include: the modular cavity having the modulator quantum wells with a first Fabry Perot resonance dip; and the laser cavity having the laser quantum wells with a second Fabry Perot resonance dip that is unaligned with the first Fabry Perot resonance dip when there is no applied bias to the modulator cavity. In one aspect, the modulator has sufficient reverse bias applied thereto, the first Fabry Perot resonance dips align with the second Fabry Perot resonance dips. In one aspect, the laser device can include: a bottom substrate under the bottom lasing mirror; and a high speed contact coupled with the bottom substrate. In one aspect, the modulator contact is a high speed low capacitance contact. In one aspect, the laser can include a laser cavity extension between the laser cavity and bottom laser mirror. In one aspect, the aperture is about 5 microns.

In one aspect, the laser device can include a mesa region that includes the: bottom modulator mirror over the top lasing mirror; modulator cavity over the bottom modulator mirror; top modulator mirror over the modulator cavity; and modulator contact on top of the top modulator mirror. In one aspect, the laser device can include a base region under the mesa, the base region includes the: bottom lasing mirror; laser cavity having laser quantum wells over the bottom lasing mirror; aperture above the laser cavity; top lasing mirror over the aperture; and AC ground contact connected to the top lasing mirror. In one aspect, the mesa region has a thickness from top to bottom of 2.7 microns. In one aspect, the mesa region has a thickness from top to bottom of 5.7 microns.

In one aspect, the laser device is configured to have an RC time constant that is less than photon lifetime. In one aspect, the laser device has an RC time constant less than the bit tome of the transmitted data. In one aspect, the laser device has an RC time constant that limits the maximum frequency. In one aspect, the laser device has an RC time constant that is less than photon lifetime.

In one embodiment, the modulator quantum well includes AlGaAs. In one aspect, a barrier ramp is included on each side of the modulator quantum well.

In one embodiment, the laser device is configured such that applied reverse bias decreases the refractive index by 0.01 to 0.02 of the modulator cavity for modulation of the laser light.

In one embodiment, a laser device can include: a bottom lasing mirror; a laser cavity having laser quantum wells over the bottom lasing mirror; an aperture above the laser cavity; a top lasing mirror over the aperture; a bottom modulator mirror over the top lasing mirror; a modulator cavity having the monitor quantum wells over the bottom modulator mirror; a top modulator mirror over the modulator cavity; a modulator contact on top of the top modulator mirror; and a AC ground contact connected to the top lasing mirror. In one aspect, the modulator quantum wells have Fabry Perot resonance dips that are unaligned with Fabry Perot resonance dips without applied reverse bias to the modulator cavity. In one aspect, the modulator quantum wells have a Fabry Perot resonance dip that is more closely aligned with laser Fabry Perot resonance dip with applied reverse bias to the modulator cavity.

In one embodiment, a laser device can include: a semiconductor having a laser region integrated with a modulator region such that the modulator region is configured to modify the spatial extent and position of the electron wavefunction and hole wavefunction using an applied field in a PIN region thereof, which modified spatial extend and position causes a change in absorption and/or refractive index sufficiently to modulate laser light emitted from the laser region.

In one embodiment, a semiconductor laser device can include: a resonant integrated modulator cavity configured such that if a defined electric field is applied to the modulator and the index of refraction and absorption coefficient both decrease with the application of the defined electric field, then a nominal independent Fabry Perot resonance of the modulator cavity is longer than the Fabry Perot resonance of laser light emitted from a laser cavity integrated with the resonant integrated modulator cavity.

In one embodiment, a semiconductor laser device can include: a resonant integrated modulator cavity configured such that if a defined electric field is applied to the modulator, then one of the index of refraction or absorption coefficient decreases and the other increases with the application of the defined electric field, then nominal independent Fabry Perot resonance of the modulator cavity is shorter than the independent Fabry Perot resonance of laser light emitted from a laser cavity integrated with the resonant integrated modulator cavity.

In one embodiment, a semiconductor laser device can include: an wavefunction deconfinement modulator comprising: a first set of modulator quantum wells having a first configuration; and a second set of modulator quantum wells having a different second configuration. In one aspect, a difference between the first set of modulator quantum wells and the second set of modulator quantum wells is the width of the quantum wells. In one aspect, a difference between the first set of modulator quantum wells and the second set of modulator quantum wells is the composition of the quantum wells. In one aspect, a difference between the first set of modulator quantum wells and the second set of modulator quantum wells is the wavelength absorbed by of the quantum wells. In one aspect, a ratio of the first set of modulator quantum wells and the second set of modulator quantum wells is greater than about 1.8:1. The laser can include a resonant cavity, which may include the wavefunction deconfinement modulator.

In one embodiment, the laser device can include the modulator region having a secondary modulator well region adjacent to a primary modulator well region, such that the secondary modulator well region is configured to significantly contain an electron and/or hole wavefunction. In one aspect, the secondary modulator well region is configured to minimize reduction of the band edge with applied field. In one aspect, the secondary modulator well region includes non-square quantum wells. In one aspect, the non-square quantum wells are “V” shaped. In one aspect, the laser device is configured to have minimal change in back reflection during modulation of the laser light. In one aspect, the laser device is configured to have minimal change in back reflection during modulation of the laser light by being designed using the transmission matrix method.

In one embodiment, the laser device can include: a bottom substrate under the bottom lasing mirror; and a high speed contact coupled with the bottom substrate. In one aspect, the modulator contact is a high speed low capacitance contact. In one aspect, a laser cavity extension is between the laser cavity and bottom laser mirror.

In one embodiment, the laser device can include a mesa region that includes the: bottom modulator mirror over the top lasing mirror; modulator cavity over the bottom modulator mirror; top modulator mirror over the modulator cavity; and modulator contact on top of the top modulator mirror. In one aspect, the laser device includes a base region under the mesa, the base region includes the: bottom lasing mirror; laser cavity having laser quantum wells over the bottom lasing mirror; aperture above the laser cavity; top lasing mirror over the aperture; and ground contact connected to the top lasing mirror. In one aspect, the mesa region has a thickness from top to bottom of 2.7 microns. In one aspect, the mesa region has a thickness from top to bottom of 5.7 microns.

In one embodiment, a wavefunction deconfinement modulator can include: a first set of modulator quantum wells having a first configuration; and a second set of modulator quantum wells having a different second configuration. In one aspect, a difference between the first set of modulator quantum wells and the second set of modulator quantum wells is the width of the quantum wells. In one aspect, a difference between the first set of modulator quantum wells and the second set of modulator quantum wells is the composition of the quantum wells. In one aspect, a difference between the first set of modulator quantum wells and the second set of modulator quantum wells is the wavelength absorbed by of the quantum wells. In one aspect, a ratio of the first set of modulator quantum wells and the second set of modulator quantum wells is greater than about 1.8:1.

In one embodiment, a laser can include a deconfinement modulator that is not integrated with the laser, but is a separate component which can modulate reflection or transmission, or both. In one embodiment, a laser can include a deconfinement modulator that is not integrated with the laser, but is a separate component tilted with respect to the incident laser light to provide a useful path for the reflected light. In one embodiment, a laser can include a deconfinement modulator that is not integrated with the laser, but is a separate component which is tilted with respect to the laser light. In one aspect, the deconfinement modulator is tilted, such that the transition strength varies with angle and polarization so that polarization components can be modulated with reflection or transmission.

In one embodiment, the deconfinement modulator is integrated with the laser and located in the laser resonant cavity and can modulate reflection or transmission, or both. In one aspect, the deconfinement modulator is integrated with the laser in the resonant cavity and tilted with respect to the incident laser light to provide a useful path for the reflected light. In one aspect, the deconfinement modulator is integrated with the laser in the resonant cavity, and is tilted with respect to the laser light. In one aspect, the deconfinement modulator is in the resonant cavity and tilted, such that the transition strength varies with angle and polarization so that polarization components can be modulated with reflection or transmission.

In one embodiment, a method of driving a deconfinement modulator can include: driving the laser with a low enough current or a high enough current such that the differential gain is reduced. In one aspect, the method includes reducing the ROF and keeping the eye open. In one aspect, the method of driving the deconfinement modulator can include operating with dual drive with a low relaxation frequency.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one ” and “one or more ” to introduce claim recitations. However, the use of such phrases should not be construed to imply that the introduction of a claim recitation by the indefinite articles “a” or “an ” limits any particular claim containing such introduced claim recitation to embodiments containing only one such recitation, even when the same claim includes the introductory phrases “one or more ” or “at least one” and indefinite articles such as “a” or “an ” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

All references recited herein are incorporated herein by specific reference in their entirety. U.S. Pat. No. 7,983,572; U.S. Ser. No. 14/698,180; HAO FENG, J. P. PANG, M. SUGIYAMA, KUNIO TADA, AND YOSHIAKI NAKANO, Field-Induced Optical Effect in a Five-Step Asymmetric Coupled Quantum Well with Modified Potential, IEEE JOURNAL OF QUANTUM ELECTRONICS, VOL. 34, NO. 7, JULY 1998, pp 1197-1208; JASON THALKEN, WEIFEI LI, STEPHAN HAAS, AND A. F. J. LEVI, Adaptive Design of Excitonic Absorption in Broken-Symmetry Quantum Wells, Jan. 4, 2014, pp 1-4; W. Q. CHEN, S. M. WANG, AND T. G. ANDERSSON, Large Stark Shifts of the Interband Transition in Two-step Quantum Wells, IEEE ELECTRON DEVICE LETTERS, VOL. 14, NO. 6, JUNE 1993, pp 286-288; J. RADOVANOVIC, V. MILANOVIC, Z. IKONIC and D. INDJIN, Quantum-Well Profile Optimization For Maximal Stark Effect And Application To Tunable Infrared Photodetectors, JOURNAL OF APPLIED PHYSICS VOLUME 91, NUMBER 1 1 JANUARY 2002, pp 525-527; TIM DAVID GERMANN, WERNER HOFMANN, 1 ALEXEY M. NADTOCHIY, JAN-HINDRIK SCHULZE, ALEX MUTIG, ANDRÉ STRITTMATTER, AND DIETER BIMBERG, Electro-Optical Resonance Modulation Of Vertical-Cavity Surface-Emitting Lasers, Received 20 Oct. 2011; accepted 2 Jan. 2012; published 16 Feb. 2012, (C) 2012 OSA 13 Feb. 2012/Vol. 20, No. 4/OPTICS EXPRESS 5099; and D. K. SERKLAND, G. M. PEAKE, AND K. M. GEIB, “VCSEL modulation using an integrated electro-absorption modulator,” in Conference on Lasers and Electro-Optics/International Quantum Electronics Conference and Photonic Applications Systems Technologies, Technical Digest (CD) (Optical Society of America, 2004), paper CTuAA2.

1. A method of modulating a laser device having an integrated modulator, the method comprising:
emitting laser light from a primary laser cavity having quantum wells;
passing the laser light through a modulator cavity having at least one modulator quantum well that is coupled with the primary laser cavity and integrated with the laser device; and
biasing the modulator cavity so as to deconfine electron and/or hole wavefunctions in the at least one modulator quantum well of the modulator cavity such that the refractive index and absorption of the modulator cavity changes to modulate the laser light passing through the modulator.

2. The method of claim 1, comprising at least partially containing the deconfined electron and/or hole wavefunctions in a secondary modulator well region adjacent to a primary modulator well region, the primary modulator well region containing the at least one modulator quantum well.

3. The method of claim 2, wherein the secondary modulator well region is designed to minimize the reduction of a band edge with an applied field by having a “V” shaped secondary modulator quantum well, the method including minimizing a reduction of the band edge.

4. The method of claim 3, comprising minimizing a change in back reflection during lasing and/or modulation of the laser light.

5. The method of claim 1, wherein the modulator quantum wells include two or more different modulator quantum well structures, wherein at least one modulator quantum well structure absorbs a shorter wavelength of laser light than other modulator quantum well structures.

6. The method of claim 1, the modulator cavity including a first set of modulator quantum wells that absorb a range of short first wavelengths and a second set of modulator quantum wells that absorb a range of different long second wavelengths, a ratio of the first set of modulator quantum wells to the second set of modulator quantum wells (first set: second set) being greater than 1.8:1.

7. The method of claim 1, comprising operating the laser device to have greater than 50 GHz bandwidth.

8. The method of claim 1, comprising operating the laser device to have greater than 100 Gb/s.

9. The method of claim 1, wherein the primary laser cavity and modulator cavity are in integrated semiconductor regions, such as by epitaxial integration.

10. The method of claim 1, comprising tuning resonance of the modulator cavity about the lasing wavelength by changing the refractive index and changing the absorption.

11. The method of claim 1, comprising changing the refractive index and changing absorption to cooperatively maintain back reflection into the laser cavity to be substantially constant.

12. The method of claim 1, comprising operating the laser device so that the modulator cavity causes a low slope efficiency, and the modulator cavity has high absorption of the laser light.

13. The method of claim 1, comprising operating the laser device so that Fabry Perot resonance of the modulator cavity is detuned from the lasing wavelength in order to enhance back reflection, wherein the enhanced back reflection is sufficient enough to maintain back reflection by countering back reflection that is lost due to absorption in the modulator cavity.

14. The method of claim 1, comprising operating the modulator cavity to have high absorption and high reflection in an absorption state and then to have low absorption and low reflection in a transmission state, which is performed with substantially constant total back reflection.

15. The method of claim 1, comprising modulating an overlap integral of the electron wavefunction and hole wavefunction by applying reverse bias to the modulating cavity so as to substantially deconfine the electron and/or hole wavefunctions.

16. The method of claim 1, comprising configuring the modulator resonance band to not coincide with the lasing wavelength of the laser cavity.

17. The method of claim 1, comprising operating a heating element associated with the laser device to heat the laser cavity and modulator cavity.

18. The method of claim 17, comprising operating the laser device in an environmental temperature range from −40 to 110 degrees C.

19. The method of claim 1, wherein the laser light emitted from the laser cavity has a wavelength of from about 820 nm to about 880 nm.

20. The method of claim 1, comprising:
applying more reverse bias to the modulator cavity to reduce absorption; and
applying less reverse bias to the modulator cavity to increase absorption,
wherein the laser light is modulated by the change in reverse bias.
